(19) United States
(12) Patent Application Publication
(10) Pub. No.: US 2014/0268275 A1
(43) Pub. Date: Sep. 18, 2014

(54) DISPLAY APPARATUS INCORPORATING AN INTERCONNECT-SUPPORTING ELEVATED APERTURE LAYER

(71) Applicant: PIXTRONIX, INC., San Diego, CA (US)

(72) Inventors: Timothy Brosnihan, Natick, MA (US); Stephen English, Billerica, MA (US); Javier Villarreal, Somerville, MA (US); Richard Payne, Andover, MA (US); Mark Kline, Concord, MA (US); Stephen R. Lewis, Reading, MA (US); Nesbitt Hagood, Gloucester, MA (US); Eugene Fike, Amesbury, MA (US)

(73) Assignee: PIXTRONIX, INC., San Diego, CA (US)

(21) Appl. No.: 13/843,135

(22) Filed: Mar. 15, 2013

(51) Int. Cl. G02B 26/02; H05K 13/00; B81B 7/00

(52) U.S. Cl. CPC G02B 26/02; B81B 7/008; H05K 13/00
USPC 359/230; 29/846

(57) ABSTRACT

This disclosure provides systems, methods and apparatus for displaying images. Some such apparatus include a transparent substrate, a display element formed on the substrate, a light blocking elevated aperture layer (EAL) supported over the substrate by an anchor formed on the substrate, and an electrical interconnect disposed on the EAL for carrying an electrical signal to the display element. The electrical interconnect can include one or more of a data voltage interconnect, a scan-line interconnect or a global interconnect. In some implementations, a dielectric layer can separate the electrical interconnect from the EAL. The EAL can include an aperture formed through it that corresponds to the display element. In some implementations, a second electrical interconnect disposed on the substrate can be electrically coupled to a plurality of display elements.

### TECHNICAL FIELD

This disclosure relates to the field of electromechanical systems (EMS), and in particular, to an integrated elevated aperture layer for use in a display apparatus.

### DESCRIPTION OF THE RELATED TECHNOLOGY

Certain displays are constructed by attaching a cover sheet having an aperture layer to a substrate that supports a plurality of display elements. The aperture layer includes apertures that correspond to respective display elements. In such displays, the alignment of the apertures and the display elements affects image quality. Accordingly, when attaching the cover sheet to the substrate, extra care is taken to make sure that the apertures are closely aligned with the respective display elements. This increases the cost of assembling such displays. Further, such displays also include spacers that are used to maintain a reasonably safe distance between the cover sheet and the nearby display elements supported by the substrate to reduce the risk of damage caused by external forces, such as a person pressing on the display. These spacers are also expensive to manufacture thereby increasing the manufacturing costs. In addition, a large distance between the cover sheet and the display elements adversely affects image quality. In particular, it reduces the contrast ratio of a display. To decrease the distance, the cover sheet and substrate can be coupled together with only a small gap between the two, however, this can increase the risk of damage if the display elements and cover sheet contact one another.

### SUMMARY

The systems, methods and devices of the disclosure each have several innovative aspects, no single one of which is solely responsible for the desirable attributes disclosed herein.

An innovative aspect of the subject matter described in this disclosure can be implemented in an apparatus that includes an apparatus that includes a transparent substrate, a light blocking elevated aperture layer (EAL), a plurality of anchors for supporting the EAL over the substrate, and a plurality of display elements. The EAL defines a plurality of apertures formed therethrough. The plurality of display elements are positioned between the substrate and the EAL. Each of the display elements corresponds to at least one respective aperture of the plurality of apertures defined by the EAL and each display element includes a movable portion supported over the substrate by a corresponding anchor that supports the EAL over the substrate. In some implementations, the display elements include microelectromechanical systems (MEMS) shutter-based display elements.

In some implementations, the apparatus includes a second substrate positioned on a side of the EAL opposite to the substrate. In some such implementations, the EAL can be adhered to a surface of the second substrate. In some other of such implementations, the apparatus includes a layer of reflective material deposited on one of a surface of the EAL nearest the second substrate and the second substrate facing the EAL.

In some implementations, the EAL includes at least one of a plurality of ribs and a plurality of anti-stiction projections extending towards the substrate. In some other implementations, the apparatus includes light dispersion elements disposed in optical paths passing through the apertures defined by the EAL. In some such implementations, the light dispersion elements include at least one of a lens and a scattering element. In some other of such implementations, the light dispersion element includes a patterned dielectric.

In some implementations, the apparatus includes a plurality of electrically isolated conductive regions corresponding to respective display elements. In some such implementations, the electrically isolated conductive regions are electrically coupled to portions of the respective display elements.

In some implementations, the apparatus also includes a display, a processor, and a memory device. The processor can be configured to communicate with the display and to process image data. The memory device can be configured to communicate with the processor. In some implementations, the apparatus also includes a driver circuit configured to send at least one signal to the display. In some such implementations, the processor is further configured to send at least a portion of the image data to the driver circuit. In some other implementations, the apparatus also can include an image source module configured to send the image data to the processor. The image source module can include at least one of a receiver, a transceiver, and a transmitter. In some other implementations, the apparatus includes an input device configured to receive input data and to communicate the input data to the processor.

Another innovative aspect of the subject matter described in this disclosure can be implemented in a method of forming a display apparatus. The method includes fabricating a plurality of display elements on a display element mold formed on a substrate. The display elements include corresponding anchors for supporting portions of the respective display elements over the substrate. The method also includes depositing a first layer of sacrificial material over the fabricated display elements and patterning the first layer of sacrificial material to expose the display element anchors. The method also includes depositing a layer of structural material over the first layer of sacrificial material such that the deposited structural material is deposited in part on the exposed display anchors and patterning the layer of structural material to define a plurality of apertures therethrough corresponding to respective display elements to form an elevated aperture layer (EAL). In addition, the method includes removing the display element mold and the first layer of sacrificial material.

In some implementations, the method also includes depositing a second layer of sacrificial material over the first layer of sacrificial material and patterning the second layer of sacrificial material to form a mold for a plurality of EAL stiffening ribs or a plurality of anti-stiction projections extending from the EAL towards the suspended portions of the respective display elements. In some other implementations, the method includes bringing regions of the EAL into contact with a surface of second substrate such that the regions of the EAL adhere to the surface of the second substrate. In some other implementations, the method includes depositing a layer of dielectric over the layer of structural material and patterning the layer of dielectric to define light dispersion elements over the apertures defined through the layer of structural material.

In some implementations, the layer of structural material includes a conductive material. In some of such implementations, patterning the layer of structural material electrically isolates neighboring regions of the EAL. Each electrically isolated region of the EAL can be electrically coupled to the suspended portion of a respective display element.

Another innovative aspect of the subject matter described in this disclosure can be implemented in an apparatus that includes a substrate, an EAL that defines a plurality of apertures formed therethrough. The EAL also includes a polymer material encapsulated by a structural material. The apparatus also includes a plurality of display elements positioned between the substrate and the EAL. Each display element corresponds to a respective aperture of the plurality of apertures.

In some other implementations, the apparatus includes a light absorbing layer deposited on a surface of the EAL. In some other implementations, the substrate includes a layer of light-blocking material. In some such implementations, the layer of light-blocking material defines a plurality of substrate apertures corresponding to respective apertures of the EAL.

In some implementations, the structural material includes at least one of a metal, a semi-conductor, and a stack of materials. In some other implementations, the EAL includes a first structural layer, a first polymer layer and a second structural layer such that the first structural layer and the second structural layer encapsulate the first polymer layer.

In some implementations, the EAL includes a plurality of electrically isolated conductive regions corresponding to respective display elements. In some such implementations, the electrically isolated conductive regions are electrically coupled to portions of the respective display element. In some other of such implementations, the electrically isolated conductive regions are electrically coupled to the portions of the respective display elements via anchors that support the respective display elements over the substrate. In some such implementations, the anchors supporting the portions of the respective display elements over the substrate also support the EAL over the display elements.

Another innovative aspect of the subject matter described in this disclosure can be implemented in a method of forming a display apparatus. The method includes forming a plurality of display elements on a display element mold formed on a substrate, depositing a first layer of sacrificial material over the display elements, patterning the first layer of sacrificial material to expose a plurality of anchors, forming an elevated aperture layer (EAL) over the first layer of sacrificial material, and removing the display element mold and the first layer of sacrificial material.

Forming the EAL can include depositing a first layer of structural material over the first layer of sacrificial material such that the deposited structural material is deposited in part on the exposed anchors, patterning the first layer of structural material to define a plurality of lower EAL apertures corresponding to respective display elements, depositing a layer of polymer material over the first layer of structural material, patterning the layer of polymer material to define a plurality of middle EAL apertures substantially in alignment with corresponding lower EAL apertures, depositing a second layer of structural material over the layer of polymer material to encapsulate the layer of polymer material between the first layer of structural material and the second layer of structural material, and patterning the second layer of structural material to define a plurality of upper EAL apertures substantially in alignment with corresponding middle and lower EAL apertures.

In some implementations, the exposed anchors support portions of corresponding display elements over the substrate. In some other implementations, the exposed anchors are distinct from a set of anchors supporting portions of the display elements over the substrate.

In some implementations, the method further includes depositing at least one of a light absorbing layer or a light reflective layer over the second layer of structural material.

Another innovative aspect of the subject matter described in this disclosure can be implemented in an apparatus that includes a transparent substrate, a display element formed on the substrate, a light blocking EAL supported over the substrate by an anchor formed on the substrate, and an electrical interconnect disposed on the EAL for carrying an electrical signal to the display element. The EAL has an aperture formed through it that corresponds to the display element. In some implementations, the EMS display element include microelectromechanical systems (MEMS) shutter-based display element.

In some implementations, the apparatus further includes at least one electrical component coupled to the electrical interconnect. In some such implementations, the electrical interconnect is coupled to a first electrical component of the at least one electrical component corresponding to the display element and to a second electrical component of the at least one electrical component corresponding to a second display element formed on the substrate. In some such implementations, the electrical component includes at least one of one of a capacitor and a transistor coupled to the electrical interconnect. In some such implementations, the transistor includes an indium gallium zinc oxide (IGZO) channel.

In some implementations, the electrical interconnect is electrically coupled to the anchor such that the anchor transmits the electrical signal to the display element. In some other implementations, the electrical interconnect includes one of a data voltage interconnect, a scan-line interconnect or a global interconnect. In some implementations, the apparatus includes a dielectric layer separating the electrical interconnect from the EAL. In some other implementations, the apparatus includes a second electrical interconnect disposed on the substrate electrically coupled to a plurality of display elements.

In some implementations, the EAL includes an electrically isolated conductive region corresponding to the display element. In some such implementations, the electrically isolated conductive region is electrically coupled to a portion of the display element. In some implementations, the electrically isolated conductive region is electrically coupled to the portion of the display element via a second anchor that supports the display element over the substrate. In some other implementations, the anchor supporting the EAL over the substrate also supports a portion of the display element over the substrate, and the electrically isolated conductive region is electrically coupled to the suspended portion of the display element via the anchor.

In some implementations, the apparatus also includes a display, a processor, and a memory device. The processor can be configured to communicate with the display and to process image data. The memory device can be configured to communicate with the processor. In some implementations, the apparatus also includes a driver circuit configured to send at least one signal to the display. In some such implementations, the processor is further configured to send at least a portion of the image data to the driver circuit. In some other implementations, the apparatus also can include an image source module configured to send the image data to the processor. The image source module can include at least one of a receiver, a transceiver, and a transmitter. In some other implementations, the apparatus includes an input device configured to receive input data and to communicate the input data to the processor.

Another innovative aspect of the subject matter described in this disclosure can be implemented in a method of manufacturing a display apparatus. The method includes providing a transparent substrate and forming a display element on the substrate. A light blocking layer is formed over the substrate, supported by an anchor formed on the substrate. The method further includes forming an aperture through the light blocking layer to form an EAL, where the aperture corresponds to the display element. An electrical interconnect is formed on top of the EAL for carrying an electrical signal to the display element.

In some implementations, the method includes depositing a layer of electrically insulating material over the EAL prior to forming the electrical interconnect. In some such implementations, the EAL includes a conductive material and the method further includes patterning the layer of electrically insulating material to expose portions of the EAL prior to forming the electrical interconnect. Forming the electrical interconnect can include depositing a layer of conductive material over the layer of electrically insulating material and patterning the layer of electrically conductive material to form the electrical interconnect such that a portion of the electrical interconnect contacts the exposed portion of the EAL.

In some other implementations, the method also includes depositing a layer of semiconducting material over the formed electrical interconnect and patterning the layer of semiconductor channel to form a portion of a transistor. In some implementations, the layer of semi-conducting material includes a metal oxide. In some other implementations, the method includes forming an electrical interconnect on the substrate prior to forming the display element.

Another innovative aspect of the subject matter described in this disclosure can be implemented in an apparatus that includes an array of display elements coupled to a substrate, and an EAL suspended over the array of display elements and coupled to the substrate. The EAL includes for each of the display elements at least one aperture defined through the EAL for allowing passage of light therethrough, a layer of light blocking material including a light blocking region for blocking light not passing through the at least one aperture, and an etch hole formed outside the light blocking region configured to allow the passage of a fluid through the EAL. In some implementations, the display elements include microelectromechanical systems (MEMS) shutter-based display elements.

In some implementations, the etch holes are positioned at about the intersection between neighboring the light blocking regions of neighboring display elements. In some implementations, the etch holes can extend about half the distance between neighboring the light blocking regions of neighboring display elements.

In some other implementations, the apparatus includes a sacrificial mold on which the array of display elements and the EAL are formed. The sacrificial mold can include a material that sublimates at a temperature less than about 500° C. In some such implementations, the mold includes norbornene or a derivative of norbornene.

In some implementations, the apparatus also includes a display, a processor, and a memory device. The processor can be configured to communicate with the display and to process image data. The memory device can be configured to communicate with the processor. In some implementations, the apparatus also includes a driver circuit configured to send at least one signal to the display. In some such implementations, the processor is further configured to send at least a portion of the image data to the driver circuit. In some other implementations, the apparatus also can include an image source module configured to send the image data to the processor. The image source module can include at least one of a receiver, a transceiver, and a transmitter. In some other implementations, the apparatus includes an input device configured to receive input data and to communicate the input data to the processor.

Another innovative aspect of the subject matter described in this disclosure can be implemented in an apparatus that includes an array of display elements coupled to a substrate and an EAL suspended over the array of display elements. The EAL is coupled to the substrate, and includes, for each of the display elements, at least one aperture for allowing passage of light therethrough. The apparatus also includes a plurality of anchors supporting the EAL over the substrate and a polymer material at least partially surrounding a portion of the plurality of anchors.

In some implementations, the polymer material extends away from the anchors outside of a set of optical paths through the apertures included in the EAL. In some other implementations, the polymer material extends away from the anchors outside of a path of travel of mechanical components of the display elements.

Another innovative aspect of the subject matter described in this disclosure can be implemented in an apparatus that includes a substrate, a first set of layers of sacrificial material defining a mold for anchors, actuators, and a light modulator of a display element, and a second set of sacrificial materials disposed over the first set of layers of sacrificial material defining a mold for an EAL. The layers of sacrificial material in at least one of the first and second sets of layers of sacrificial material include a material that sublimates at a temperature below about 500° C. In some implementations, the layers of sacrificial material in at least one of the first and second sets of layers of sacrificial material include norbornene or a derivative of norbornene.

In some implementations, the apparatus also includes a layer of structural material disposed between the first set of layers of sacrificial material and the second set of layers of sacrificial material.

In some implementations, the second set of layers of sacrificial material includes a lower layer and an upper layer. In some such implementations, the upper layer includes a plurality of recesses that define molds for ribs extending from the EAL towards the substrate, a plurality of mesas that define molds for ribs extending from the EAL away from the substrate, or a plurality of recesses that define molds for anti-stiction projections extending from the EAL towards the substrate.

Another innovative aspect of the subject matter described in this disclosure can be implemented in a method of manufacturing. The method includes forming an electromechanical systems (EMS) display element on a first mold formed on a substrate. The EMS display element includes a portion suspended over the substrate. The method also includes forming an EAL on a second mold formed over the EMS display element, partially removing at least a first portion of at least one of the first and second molds by applying a wet etch, and partially removing at least a second portion of at least one of the first and second molds by a applying a dry plasma etch.

In some implementations, applying the wet etch and the dry plasma etch together remove the first and second molds substantially in their entirety. In some other implementations, applying the wet etch and the dry plasma etch leaves a third portion of at least one of the first and second molds intact. In some such implementations, the third portion at least partially surrounds an anchor supporting the EAL over the substrate.

In some implementations, the method also includes forming etch holes through the EAL. The wet etch and dry etch are applied to at least one of the first and second molds through the etch holes.

Details of one or more implementations of the subject matter described in this specification are set forth in the accompanying drawings and the description below. Although the examples provided in this summary are primarily described in terms of MEMS-based displays, the concepts provided herein may apply to other types of displays, such as liquid crystal displays (LCDs), organic light emitting diode (OLED) displays, electrophoretic displays, and field emission displays, as well as to other non-display MEMS devices, such as MEMS microphones, sensors, and optical switches. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a schematic diagram of an example direct-view MEMS-based display apparatus.

FIG. 1B shows a block diagram of an example host device.

FIG. 2 shows a perspective view of an example shutter-based light modulator.

FIGS. 3A and 3B show portions of two example control matrices.

FIG. 4 shows a cross-sectional view of an example display apparatus incorporating flexible conductive spacers.

FIG. 5A shows a cross-sectional view of an example display apparatus incorporating an integrated elevated aperture layer (EAL).

FIG. 5B shows a top view of an example portion of the EAL shown in FIG. 5A.

FIG. 6A shows a cross-sectional view of an example display apparatus incorporating an integrated EAL.

FIG. 6B shows a top view of an example portion of the EAL shown in FIG. 6A.

FIGS. 6C-6E show top views of portions of additional example EALs.

FIG. 7 shows a cross-sectional view of an example display apparatus incorporating an EAL.

FIG. 8 shows a cross-sectional view of a portion of an example MEMS down display apparatus.

FIG. 9 shows a flow diagram of an example process for manufacturing a display apparatus.

FIGS. 10A-10I show cross-sectional views of stages of construction of an example display apparatus according to the manufacturing process shown in FIG. 9.

FIG. 11A shows a cross-sectional view of an example display apparatus incorporating an encapsulated EAL.

FIGS. 11B-11D show cross-sectional views of stages of construction of the example display apparatus shown in FIG. 11A.

FIG. 12A shows a cross-sectional view of an example display apparatus incorporating a ribbed EAL.

FIGS. 12B-12E show cross-sectional views of stages of construction of the example display apparatus shown in FIG. 12A.

FIG. 12F shows a cross-sectional view of an example display apparatus.

FIGS. 12G-12J show plan views of example rib patterns suitable for use in the ribbed EALs of FIGS. 12A and 12E

FIG. 13 shows a portion of a display apparatus incorporating an example EAL having light dispersion structures.

FIGS. 14A-14H shows top views of example portions of EALs incorporating light dispersion structures.

FIG. 15 shows a cross-sectional view of an example display apparatus incorporating an EAL that includes a lens structure.

FIG. 16 shows a cross-sectional view of an example display apparatus having an EAL.

FIG. 17 shows a perspective view of a portion of an example display apparatus.

FIG. 18A is a cross-sectional view of an example display apparatus.

FIGS. 18B and 18C show cross sectional views of additional example display apparatus.

FIG. 19 shows a cross-sectional view of an example display apparatus.

FIGS. 20A and 20B show system block diagrams illustrating an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (such as e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations shown solely in the Figures, but instead have wide applicability as will be readily apparent to one having ordinary skill in the art.

Certain shutter-based display apparatus can include circuits for controlling an array of shutter assemblies that modulate light to generate display images. The circuits used to control the states of the shutter assemblies can be arranged into a control matrix. The control matrix addresses each pixel of the array to either be in a light transmissive state or a light blocking state for any given image frame. In some implementations, responsive to data signals, the drive circuits of the control matrix selectively store actuation voltages onto the shutters of the shutter assemblies.

To selectively store data voltages on shutters without incurring substantial risks of shutter stiction, electrically isolated portions of an opposing surface are electrically coupled to respective shutters, such that they remain at the same potential. In some implementations, the shutters are electrically coupled to electrically isolated portions of a conductive layer disposed on an opposing substrate using compressible conductive spacers.

In some other implementations, the shutters are electrically coupled to electrically isolated portions of an elevated aperture layer (EAL) formed on the same substrate as the shutter assemblies. In some such implementations, the shutters and the EAL are electrically coupled by anchors used to support the shutters over the substrate. In some other implementations, the shutters are coupled to the EAL via separate anchors used to the support the EAL, but not the shutters, over the substrate on which they are fabricated.

In some implementations, the EAL is fabricated from or includes the same structural materials used to form the shutter assembly. In some other implementations, the EAL includes a polymer encapsulated by similar structural materials. In some implementations, a light blocking layer is disposed on a surface of the EAL. The light blocking layer is reflective in some implementations, and light absorbing, in others, depending on the orientation of the EAL in the display apparatus. In some other implementations, the EAL can include light dispersing features, such as light scattering elements or lenses, disposed across apertures formed in the EAL.

The EAL can be fabricated by first fabricating the shutter assemblies, and then forming the EAL on a mold formed over the shutter assemblies. In some implementations, the EAL mold includes a single layer of sacrificial material. In some other implementations, the EAL mold is formed from multiple layers of sacrificial material. In some such implementations, the multiple mold layers can be used to form ribs or anti-stiction projections in the EAL. In some implementations, after fabrication, portions of the EAL can be brought into contact and adhered to an opposing substrate. Apertures are formed in the EAL in alignment with apertures formed in a layer of light blocking material disposed on an underlying substrate on which the EAL was formed.

After the EAL is fabricated, the EAL and the shutter assemblies above which the EAL was fabricated are released from the mold on which they were formed. To ease the release process, etch holes can be formed through the EAL outside of regions of the EAL used to prevent light leakage. In some implementations, the release process can be facilitated by use of a two phase etching process, in which a wet etch is used initially, followed by a dry etch. In some other implementations, the shutter assemblies are configured such that incomplete release of the mold is desired, leaving mold material to help support the EAL or other components over the substrate. In some other implementations, the mold is formed from a sacrificial material that sublimates at temperatures compatible with thin-film processing, thereby avoiding the need for etching.

In some implementations, one or more electrical interconnects or other electrical components can be formed on the EAL. In some such implementations, one of column or row interconnects can be formed on top of the EAL, while the other of column or row interconnects can be formed on the underlying substrate. In some implementations, electrical components such as transistors, capacitors, diodes, or other electrical components also can be formed on the surface of the EAL.

Particular implementations of the subject matter described in this disclosure can be implemented to realize one or more of the following potential advantages. In general, the use of an EAL provides manufacturing advantages, optical advantages, and display element control advantages.

With respect to manufacturing advantages, the use of an EAL enables the fabrication of substantially all electromechanical and optical components of a display on a single substrate. This substantially increases the alignment tolerances between the substrates, and in some implementations can virtually eliminate the need to align the substrates. In addition, the inclusion of the EAL obviates the need to form an electrical connection between individual display elements on one substrate and respective regions of the other substrate. This allows the two substrates to be fabricated further apart, limiting and in some implementations the need to form spacers between the two substrates. This extra space also allows a front substrate to deform in response to temperature changes, alleviating the need for fabricating alternative bubble reduction or mitigation features within the display. In addition, the EAL does not need to deform in response to temperature changes, keeping the apertures a substantially constant distance from a rear substrate. This substantially constant distance helps maintain viewing angle performance for the display, which can be disturbed by aperture layer deformation. Furthermore, the additional space may reduce the likelihood of cavitation bubble formation resulting from impacts on the surface of the display, which can damage the display elements.

In some implementations, the EAL can be fabricated using two mold layers. Doing so allows the EAL to include anti-stiction projections or stiffening ribs. The former helps mitigate the risk of display elements adhering to the EAL. The latter helps strengthen the EAL against external pressures. In some other implementations, an EAL can be strengthened by having it enclose a layer of polymer material.

With respect to optics, the use of an EAL can improve the viewing angle characteristics of a display. A display can include a pair of opposing apertures that form a portion of optical path from a backlight to viewer to be located closer together. The distance between such apertures can limit the viewing angle of the display. Using an EAL can allow the opposing apertures to be placed closer to one another, thereby improving viewing angle characteristics. In addition, optical structures can be fabricated on top of apertures defined by an EAL. These structures can disperse light, further improving viewing angle characteristics of the display.

In some implementations, the EAL can be fabricated such that it is supported by some of the same anchors that support portions of display elements over a substrate. This reduces the number of structures needed to support the EAL, freeing additional room for electrical, mechanical, or optical components, including additional display elements in higher pixel-per-inch (PPI) displays. Such a configuration also provides a ready means for electrically linking portions of individual display elements to respective isolated conductive regions formed on the EAL. These display element-specific electrical connections permit alternative control circuit configurations. For example, in some such implementations, the circuits that control the states of the display elements provide a varying actuation voltage to portions of different display elements, instead of maintaining such portions at a common voltage across display elements. Such control circuits can be faster to actuate, require less space, and have higher reliability.

In some other implementations, certain components of the control circuits (also referred to as a control matrix), can be fabricated on top of the EAL, as opposed to on the surface of the substrate. For example, some interconnects included in the control matrix can be fabricated on top of the EAL, while other interconnects are formed on the substrate. Separating interconnects in such a fashion reduces the parasitic capacitance between interconnects. Other electronic components such as transistors or capacitors also can be built on the EAL. The extra real estate resulting from moving the electronics to the top of the EAL allows for higher aperture ratio displays, or higher resolution displays with smaller display elements.

As described above, various techniques can be employed to facilitate release of display elements fabricated below an EAL. For example, etch holes through the EAL can provide additional fluid pathways for etchants to reach the sacrificial mold on which the display elements and the EAL are built. This reduces the time required for release, thereby improving overall manufacturing efficiency while also limiting the exposure of the display elements and the EAL to potentially corrosive etchants, which could damage the display elements, thereby reducing their manufacturing yield or long-term durability. Such exposure also can be limited by employing a two-phase etching process. In some implementations, such exposure can be limited further by employing a sublimatable sacrificial mold. Doing so also reduces to need to form additional fluid paths through the EAL to ensure chemical etchants reach the sacrificial material in a timely fashion. In addition, designs that intentionally allow for the incomplete removal of the sacrificial mold can result in stronger display element anchors, yielding a more durable display.

FIG. 1A shows a schematic diagram of an example direct-view microelectromechanical system (MEMS)-based display apparatus 100. The display apparatus 100 includes a plurality of light modulators 102a-102d (generally “light modulators 102”) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide luminance level in an image 104. With respect to an image, a “pixel” corresponds to the smallest picture element defined by the resolution of image. With respect to structural components of the display apparatus 100, the term “pixel” refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the user sees the image by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or “backlight” so that each pixel can be uniformly illuminated. Transmissive direct-view displays are often built onto transparent or glass substrates to facilitate a sandwich assembly arrangement where one substrate, containing the light modulators, is positioned directly on top of the backlight.

Each light modulator 102 can include a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix connected to the substrate and to the light modulators for controlling the movement of the shutters. The control matrix includes a series of electrical interconnects (e.g., interconnects 110, 112 and 114), including at least one write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage, V_{WE}”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as, transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B shows a block diagram 120 of an example host device (i.e., cell phone, smart phone, PDA, MP3 player, tablet, e-reader, etc.). The host device includes a display apparatus 128, a host processor 122, environmental sensors 124, a user input module 126, and a power source.

The display apparatus 128 includes a plurality of scan drivers 130 (also referred to as “write enabling voltage sources”), a plurality of data drivers 132 (also referred to as “data voltage sources”), a controller 134, common drivers 138, lamps 140-146, and lamp drivers 148. The scan drivers 130 apply write enabling voltages to write-enable interconnects 110. The data drivers 132 apply data voltages to the data interconnects 112.

In some implementations of the display apparatus, the data drivers 132 are configured to provide analog data voltages to the light modulators, especially where the luminance level of the image 104 is to be derived in analog fashion. In analog operation, the light modulators 102 are designed such that when a range of intermediate voltages is applied through the data interconnects 112, there results a range of intermediate open states in the shutters 108 and therefore a range of intermediate illumination states or luminance levels in the image 104. In other cases, the data drivers 132 are configured to apply only a reduced set of 2, 3 or 4 digital voltage levels to the data interconnects 112. These voltage levels are designed to set, in digital fashion, an open state, a closed state, or other discrete state to each of the shutters 108.

The scan drivers 130 and the data drivers 132 are connected to a digital controller circuit 134 (also referred to as the “controller 134”). The controller sends data to the data drivers 132 in a mostly serial fashion, organized in sequences, which in some implementations may be predetermined, grouped by rows and by image frames. The data drivers 132 can include series to parallel data converters, level shifting, and for some applications digital to analog voltage converters.

The display apparatus optionally includes a set of common drivers 138, also referred to as common voltage sources. In some implementations, the common drivers 138 provide a DC common potential to all light modulators within the array of light modulators, for instance by supplying voltage to a series of common interconnects 114. In some other implementations, the common drivers 138, following commands from the controller 134, issue voltage pulses or signals to the array of light modulators, for instance global actuation pulses which are capable of driving and/or initiating simultaneous actuation of all light modulators in multiple rows and columns of the array.

All of the drivers (e.g., scan drivers 130, data drivers 132 and common drivers 138) for different display functions are time-synchronized by the controller 134. Timing commands from the controller coordinate the illumination of red, green and blue and white lamps (140, 142, 144 and 146 respectively) via lamp drivers 148, the write-enabling and sequencing of specific rows within the array of pixels, the output of voltages from the data drivers 132, and the output of voltages that provide for light modulator actuation.

The controller 134 determines the sequencing or addressing scheme by which each of the shutters 108 can be re-set to the illumination levels appropriate to a new image 104. New images 104 can be set at periodic intervals. For instance, for video displays, the color images 104 or frames of video are refreshed at frequencies ranging from 10 to 300 Hertz (Hz). In some implementations the setting of an image frame to the array is synchronized with the illumination of the lamps 140, 142, 144 and 146 such that alternate image frames are illuminated with an alternating series of colors, such as red, green and blue. The image frames for each respective color is referred to as a color subframe. In this method, referred to as the field sequential color method, if the color subframes are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green and blue.

In some implementations, where the display apparatus 100 is designed for the digital switching of shutters 108 between open and closed states, the controller 134 forms an image by the method of time division gray scale, as previously described. In some other implementations, the display apparatus 100 can provide gray scale through the use of multiple shutters 108 per pixel.

In some implementations, the data for an image state 104 is loaded by the controller 134 to the modulator array by a sequential addressing of individual rows, also referred to as scan lines. For each row or scan line in the sequence, the scan driver 130 applies a write-enable voltage to the scan-line interconnect 110 for that row of the array, and subsequently the data driver 132 supplies data voltages, corresponding to desired shutter states, for each column in the selected row. This process repeats until data has been loaded for all rows in the array. In some implementations, the sequence of selected rows for data loading is linear, proceeding from top to bottom in the array. In some other implementations, the sequence of selected rows is pseudo-randomized, in order to minimize visual artifacts. And in some other implementations, the sequencing is organized by blocks, where, for a block, the data for only a certain fraction of the image state 104 is loaded to the array, for instance by addressing only every 5^{th} row of the array in sequence.

In some implementations, the process for loading image data to the array is separated in time from the process of actuating the shutters 108. In these implementations, the modulator array may include data memory elements for each pixel in the array and the control matrix may include a global actuation interconnect for carrying trigger signals, from common driver 138, to initiate simultaneous actuation of shutters 108 according to data stored in the memory elements.

In alternative implementations, the array of pixels and the control matrix that controls the pixels may be arranged in configurations other than rectangular rows and columns. For example, the pixels can be arranged in hexagonal arrays or curvilinear rows and columns. In general, as used herein, the term scan-line shall refer to any plurality of pixels that share a write-enabling interconnect.

The host processor 122 generally controls the operations of the host. For example, the host processor may be a general or special purpose processor for controlling a portable electronic device. With respect to the display apparatus 128, included within the host device 120, the host processor outputs image data as well as additional data about the host. Such information may include data from environmental sensors, such as ambient light or temperature; information about the host, including, for example, an operating mode of the host or the amount of power remaining in the host's power source; information about the content of the image data; information about the type of image data; and/or instructions for display apparatus for use in selecting an imaging mode.

The user input module 126 conveys the personal preferences of the user to the controller 134, either directly, or via the host processor 122. In some implementations, the user input module is controlled by software in which the user programs personal preferences such as “deeper color,” “better contrast,” “lower power,” “increased brightness,” “sports,” “live action,” or “animation.” In some other implementations, these preferences are input to the host using hardware, such as a switch or dial. The plurality of data inputs to the controller 134 direct the controller to provide data to the various drivers 130, 132, 138 and 148 which correspond to optimal imaging characteristics.

An environmental sensor module 124 also can be included as part of the host device. The environmental sensor module receives data about the ambient environment, such as temperature and or ambient lighting conditions. The sensor module 124 can be programmed to distinguish whether the device is operating in an indoor or office environment versus an outdoor environment in bright daylight versus and outdoor environment at nighttime. The sensor module communicates this information to the display controller 134, so that the controller can optimize the viewing conditions in response to the ambient environment.

FIG. 2 shows a perspective view of an illustrative shutter-based light modulator 200. The shutter-based light modulator is suitable for incorporation into the direct-view MEMS-based display apparatus 100 of FIG. 1A. The light modulator 200 includes a shutter 202 coupled to an actuator 204. The actuator 204 can be formed from two separate compliant electrode beam actuators 205 (the “actuators 205”). The shutter 202 couples on one side to the actuators 205. The actuators 205 move the shutter 202 transversely over a substrate 203 in a plane of motion which is substantially parallel to the substrate 203. The opposite side of the shutter 202 couples to a spring 207 which provides a restoring force opposing the forces exerted by the actuator 204.

Each actuator 205 includes a compliant load beam 206 connecting the shutter 202 to a load anchor 208. The load anchors 208 along with the compliant load beams 206 serve as mechanical supports, keeping the shutter 202 suspended proximate to the substrate 203. The surface includes one or more aperture holes 211 for admitting the passage of light. The load anchors 208 physically connect the compliant load beams 206 and the shutter 202 to the substrate 203 and electrically connect the load beams 206 to a bias voltage, in some instances, ground.

If the substrate is opaque, such as silicon, then aperture holes 211 are formed in the substrate by etching an array of holes through the substrate 204. If the substrate 204 is transparent, such as glass or plastic, then the aperture holes 211 are formed in a layer of light-blocking material deposited on the substrate 203. The aperture holes 211 can be generally circular, elliptical, polygonal, serpentine, or irregular in shape.

Each actuator 205 also includes a compliant drive beam 216 positioned adjacent to each load beam 206. The drive beams 216 couple at one end to a drive beam anchor 218 shared between the drive beams 216. The other end of each drive beam 216 is free to move. Each drive beam 216 is curved such that it is closest to the load beam 206 near the free end of the drive beam 216 and the anchored end of the load beam 206.

In operation, a display apparatus incorporating the light modulator 200 applies an electric potential to the drive beams 216 via the drive beam anchor 218. A second electric potential may be applied to the load beams 206. The resulting potential difference between the drive beams 216 and the load beams 206 pulls the free ends of the drive beams 216 towards the anchored ends of the load beams 206, and pulls the shutter ends of the load beams 206 toward the anchored ends of the drive beams 216, thereby driving the shutter 202 transversely towards the drive beam anchor 218. The compliant load beams 206 act as springs, such that when the voltage across the beams 206 and 216 potential is removed, the load beams 206 push the shutter 202 back into its initial position, releasing the stress stored in the load beams 206.

A light modulator, such as the light modulator 200, incorporates a passive restoring force, such as a spring, for returning a shutter to its rest position after voltages have been removed. Other shutter assemblies can incorporate a dual set of “open” and “closed” actuators and separate sets of “open” and “closed” electrodes for moving the shutter into either an open or a closed state.

There are a variety of methods by which an array of shutters and apertures can be controlled via a control matrix to produce images, in many cases moving images, with appropriate luminance levels. In some cases, control is accomplished by means of a passive matrix array of row and column interconnects connected to driver circuits on the periphery of the display. In other cases, it is appropriate to include switching and/or data storage elements within each pixel of the array (the so-called active matrix) to improve the speed, the luminance level and/or the power dissipation performance of the display.

FIGS. 3A and 3B show portions of two example control matrices 800 and 860. As described above, a control matrix is a collection of interconnects and circuitry used to address and actuate the display elements of a display. In some implementations, the control matrix 800 can be implemented for use in the display apparatus 100 shown in FIG. 1B and is formed using thin-film components, such as thin-film transistors (TFTs) and other thin film components.

The control matrix 800 controls an array of pixels 802, a scan-line interconnect 806 for each row of pixels 802, a data interconnect 808 for each column of pixels 802, and several common interconnects that each carry signals to multiple rows and multiple columns of pixels at the same time. The common interconnects include an actuation voltage interconnect 810, a global update interconnect 812, a common drive interconnect 814, and a shutter common interconnect 816.

Each pixel in the control matrix includes a light modulator 804, a data storage circuit 820, and an actuation circuit 825. The light modulator 804 includes a first actuator 805a and a second actuator 805b (generally “actuators 805”) for moving a light obstructing component, such as a shutter 807, between at least an obstructive and a non-obstructive state. In some implementations, the obstructive state corresponds to a light absorbing dark state in which the shutter 807 obstructs the path of light from a backlight out towards and through the front of the display to a viewer. The non-obstructive state can correspond to a transmissive or light state, in which the shutter 807 is outside of the path of light, allowing the light emitted by the backlight to be output through the front of the display. In some other implementations, the obstructive state is a reflective state and the non-obstructive state is a light absorbing state.

The data storage circuit 820 also includes a write-enabling transistor 830, and a data storage capacitor 835. The data storage circuit 820 is controlled by the scan-line interconnect 806 and the data interconnect 808. More particularly, the scan-line interconnect 806 selectively allows data to be loaded into the pixels 802 of a row by supplying a voltage to the gates of the write-enabling transistors 830 of the respective pixel actuation circuits 825. The data interconnect 808 provides a data voltage corresponding to the data to be loaded into the pixel 802 of its corresponding column in the row for which the scan-line interconnect 806 is active. To that end, the data interconnect 808 couples the source of the write-enabling transistor 830. The drain of the write-enabling transistor 830 couples to the data storage capacitor 835. If the scan-line interconnect 806 is active, a data voltage applied to the data interconnect 808 passes through the write-enabling transistor 830 and is stored on the data storage capacitor 835.

The pixel actuation circuit 825 includes an update transistor 840 and a charge transistor 845. The gate of the update transistor 840 is coupled to the data storage capacitor 835 and the drain of the write-enable transistor 830. The drain of the update transistor 840 is coupled to the global update interconnect 812. The source of the update transistor 840 is coupled to the drain of the charge transistor 845 and a first active node 852, which is coupled to a drive electrode 809a of the first actuator 805a. The gate and source of the charge transistor 845 are connected to the actuation voltage interconnect 810.

A drive electrode 809b of the second actuator 805b is coupled to the common drive interconnect 814 at a second active node 854. The shutter 807 also is coupled to the shutter common interconnect 816, which in some implementations, is maintained at ground. The shutter common interconnect 816 is configured to be coupled to each of the shutters in the array of pixels 802. In this way, all of the shutters are maintained at the same voltage potential.

The control matrix 800 can operate in three general stages. First, data voltages for pixels in a display are loaded for each pixel one row at a time in a data loading stage. Next, in a precharge stage, the common drive interconnect 814 is grounded and actuation voltage interconnect 810 is brought high. Doing so lowers the voltage on the drive electrode 809b of the second actuators 805b of the pixels and applies a high voltage to the drive electrodes 809a of the first actuators 805a of the pixels 802. This results in all of the shutters 807 moving towards the first actuator 805, if they were not already in that position. Next, in a global update stage, the pixels 802 are moved (if necessary) to the state indicated by the data voltage loaded into the pixels 802 in the data loading stage.

The data loading stage proceeds with applying a write-enabling voltage V_{we} to a first row of the array of pixels 802 via the scan-line interconnect 806. As described above, the application of a write-enabling voltage V_{we} to the scan-line interconnect 806 corresponding to a row turns on the write-enable transistors 830 of all pixels 802 in that row. Then a data voltage is applied to each data interconnect 808. The data voltage can be high, such as between about 3V and about 7V, or it can be low, for example, at or about ground. The data voltage on each data interconnect 808 is stored on the data storage capacitor 835 of its respective pixel in the write-enabled row.

Once all the pixels 802 in the row are addressed, the control matrix 800 removes the write-enabling voltage V_{we} from the scan-line interconnect 806. In some implementations, the control matrix 800 grounds the scan-line interconnect 806. The data loading stage is then repeated for subsequent rows of the array in the control matrix 800. At the end of the data loading sequence, each of the data storage capacitors 835 in the selected group of pixels 802 stores the data voltage which is appropriate for the setting of the next image state.

The control matrix 800 then proceeds with the precharge stage. In the precharge stage, in each pixel 802, the drive electrode 809a of the first actuator 805a is charged to the actuation voltage, and the drive electrode 809b of the second actuator 805b is grounded. If the shutter 807 in the pixel 802 was not already moved towards the first actuator 805a for the previous image, then this process causes the shutter 807 to do so. The precharge stage begins by providing an actuation voltage to the actuation voltage interconnect 810 and providing a high voltage at the global update interconnect 812. The actuation voltage, in some implementations, can be between about 20V and about 50V. The high voltage applied to the global update interconnect 812 can be between about 3V and about 7V. By doing so, the actuation voltage from the actuation voltage interconnect 810 can pass through the charge transistor 845, bringing the first active node 852 and the drive electrode 809a of the first actuator 805a up to the actuation voltage. As a result, the shutter 807 either remains attracted to the first actuator 805a or moves towards the first actuator from the second actuator 805b.

The control matrix 800 then activates the common drive interconnect 814. This brings the second active node 854 and the drive electrode 809b of the second actuator 805b to the actuation voltage. The actuation voltage interconnect 810 is then brought down to a low voltage, such as ground. At this stage, the actuation voltage is stored on the drive electrodes 809a and 809b of both actuators 805. However, as the shutter 807 is already moved towards the first actuator 805a, it remains in that position unless and until the voltage on the drive electrode 809a of the first actuator is brought down. The control matrix 800 then waits a sufficient amount of time for all of the shutters 807 to reliably have reached their positions adjacent the first actuator 805a before proceeding.

Next, the control matrix 800 proceeds with the update stage. In this stage, the global update interconnect 812 is brought to a low voltage. Bringing the global update interconnect 812 down enables the update transistor 840 to respond to the data voltage stored on the data storage capacitor 835. Depending on the voltage of the data voltage stored at the data storage capacitor 835, the update transistor 840 will either switch ON or remain switched OFF. If the data voltage stored at the data storage capacitor 835 is high, the update transistor 840 switches ON, resulting in the voltage at the first active node 852 and on the drive electrode 809a of the first actuator 805a to collapse to ground. As the voltage on the drive electrode 809b of the second actuator 805b remains high, the shutter 807 moves towards the second actuator 805b. Conversely, if the data voltage stored in the data storage capacitor 835 is low, the update transistor 840 remains switched OFF. As a result, the voltage at the first active node 852 and on the drive electrode 809a of the first actuator 805a remains at the actuation voltage level, keeping the shutter in place. After enough time has passed to ensure all shutters 807 have reliably travelled to their intended positions, the display can illuminate its backlight to display the image resulting from the shutter states loaded into the array of pixels 802.

In the process described above, for each set of pixel states the control matrix 800 displays, the control matrix 800 takes at least twice the time needed for the shutter 807 to travel between states in order to ensure the shutter 807 ends up in the proper position. That is, all the shutters 807 are first brought towards the first actuator 805a, requiring one shutter travel time, before they are then selectively allowed to move towards the second actuator 805b, requiring a second shutter travel time. If the global update stage commences too quickly, the shutter 807 may not have enough time to reach the first actuator 805a. As a result, the shutter may move towards the incorrect state during the global update stage.

In contrast to shutter-based display circuits, such as the control matrix 800 shown in FIG. 3A, in which the shutters are maintained at a common voltage and are driven by varying the voltage applied to the drive electrodes 809a and 809b of opposing actuators 805a and 805b, a display circuit in which the shutter is itself coupled to an active node can be implemented. Shutters controlled by such a circuit can be directly driven into their respective desired states without first all having to be moved into a common position, as described with respect to the control matrix 800. As a result, such a circuit requires less time to address and actuate, and reduces the risk of shutters not correctly entering their desired states.

FIG. 3B shows a portion of a control matrix 860. The control matrix 860 is configured to selectively apply actuation voltages to the load electrode 811 of each actuator 805, instead of to the drive electrode 809. The load electrodes 811 are directly coupled to the shutter 807. This is in contrast to the control matrix 800 depicted in FIG. 3A, in which the shutter 807 was kept at a constant voltage.

Similar to the control matrix 800 shown in FIG. 3A, the control matrix 860 can be implemented for use in the display apparatus 100 shown in FIGS. 1A and 1B. In some implementations, the control matrix 860 also can be implemented for use in the display apparatus shown in FIGS. 4, 5A, 7, 8 and 13-18, described below. The structure of the control matrix 860 is described immediately below.

Like the control matrix 800, the control matrix 860 controls an array of pixels 862. Each pixel 862 includes a light modulator 804. Each light modulator includes a shutter 807. The shutter 807 is driven by actuators 805a and 805b between a position adjacent the first actuator 805a and a position adjacent the second actuator 805b. Each actuator 805a and 805b includes a load electrode 811 and a drive electrode 809. Generally, as used herein, a load electrode 811 of an electrostatic actuator corresponds to the electrode of the actuator coupled to the load being moved by the actuator. Accordingly, with respect to the actuators 805a and 805b, the load electrode 811 refers to an electrode of the actuator that couples to the shutter 807. The drive electrode 809 refers to the electrode paired with and opposing the load electrode 811 to form the actuator.

The control matrix 860 includes a data loading circuit 820 similar to that of the control matrix 800. The control matrix 860, however, includes different common interconnects than the control matrix 800 and a significantly different actuation circuit 861.

The control matrix 860 includes three common interconnects which were not included in the control matrix 800 of FIG. 3A. Specifically, the control matrix 860 includes a first actuator drive interconnect 872, a second actuator drive interconnect 874, and a common ground interconnect 878. In some implementations, the first actuator drive interconnect 872 is maintained at a high voltage and the second actuator drive interconnect 874 is maintained at a low voltage. In some other implementations, the voltages are reversed, i.e., the first actuator drive interconnect is maintained at a low voltage and the second actuator drive interconnect 874 is maintained at a high voltage. While the following description of the control matrix 860 assumes a constant voltage being applied to the first and second actuator drive interconnects 872 and 874 (as set forth above), in some other implementations, the voltages on the first actuator drive interconnect 872 and the second actuator drive interconnects 874, as well as the input data voltage, are periodically reversed to avoid charge build-up on the electrodes of the actuators 805 and 805b.

The common ground interconnect 878 serves merely to provide a reference voltage for data stored on the data storage capacitor 835. In some implementations, the control matrix 860 can forego the common ground interconnect 878, and instead have the data storage capacitor coupled to the first or second actuator drive interconnect 872 and 874. The function of the actuator drive interconnects 872 and 874 is described further below.

Like the control matrix 800, the actuation circuit 861 of the control matrix 860 includes an update transistor 840 and a charge transistor 845. In contrast, however, the charge transistor 845 and the update transistor 840 are coupled to the load electrode 811 of the first actuator 805a of the light modulator 804, instead of the drive electrode 809a of the first actuator 805a. As a result, when the charge transistor 845 is activated, an actuation voltage is stored on the load electrodes 811 of both of the actuators 805a and 805b, as well as on the shutter 807. Thus, the update transistor 840, instead of selectively discharging the drive electrodes 809a of the first actuator 805a, based on image data stored on the storage capacitor 835, selectively discharges the load electrodes 811 of the actuators 805a and 805b and the shutter 807, removing the potential on the components.

As indicated above, the first actuator drive interconnect 872 is maintained at a high voltage and the second actuator drive interconnect 874 is maintained at a low voltage. Accordingly, while an actuation voltage is stored on the shutter 807 and the load electrodes 811 of the actuators 805a and 805b, the shutter 807 moves to the second actuator 805b, whose drive electrode 809b is maintained at a low voltage. When the shutter 807 and the load electrodes 811 of the actuators 805a and 805b are brought low, the shutter 807 moves towards the first actuator 805a, whose drive electrode 809a is maintained at a high voltage.

The control matrix 860 can operate in two general stages. First, data voltages for pixels 862 in a display are loaded for each pixel 862, one or more rows at a time, in a data loading stage. The data voltages are loaded in a manner similar to that described above with respect to FIG. 3A. In addition, the global update interconnect 812 is maintained at a high voltage potential to prevent the update transistor 840 from switching ON during the data loading stage.

After the data loading stage is complete, the shutter actuation stage begins by providing an actuation voltage to the actuation voltage interconnect 810. By providing the actuation voltage to the actuation voltage interconnect 810, the charge transistor 845 is switched ON allowing the current to flow through the charge transistor 845, bringing the shutter 807 up to about the actuation voltage. After a sufficient period of time has passed to allow the actuation voltage to be stored on the shutter 807, the actuation voltage interconnect 810 is brought low. The amount of time needed for this to occur is substantially less than the time needed for a shutter 807 to change states. The update interconnect 812 is brought low immediately thereafter. Depending on the data voltage stored at the data storage capacitor 835, the update transistor 840 will either remain OFF or will switch ON.

If the data voltage is high, the update transistor 840 switches ON, discharging the shutter 807 and the load electrodes 811 of the actuators 805a and 805b. As a result, the shutter is attracted to the first actuator 805a. Conversely, if the data voltage is low, the update transistor 840 remains OFF. As a result, the actuation voltage remains on the shutter and the load electrodes 811 of the actuators 805a and 805b. The shutter, as a result is attracted to the second actuator 805b.

Due to the architecture of the actuation circuit 861, it is permissible for the shutter 807 to be in any state, even an indeterminate state, when the update transistor 840 is turned ON. This enables the immediate switching of the update transistor 840 as soon as the actuation voltage interconnect 810 is brought low. In contrast to the operation of the control matrix 800, with the control matrix 860, no time needs to be set aside to allow the shutter 807 to move to any particular state. Moreover, because the initial state of the shutter 807 has little to no impact on its final state, the risk of a shutter 807 entering the wrong state is substantially reduced.

Shutter assemblies employing control matrices similar to the control matrix 800 depicted in FIG. 3A face the risk of their respective shutters being drawn towards an opposing substrate due to charge build up on the substrate. If the charge build-up is sufficiently large, the resulting electrostatic forces can draw the shutter into contact with the opposing substrate, where it can sometimes permanently adhere due to stiction. To reduce this risk, a substantially continuous conductive layer can be deposited across the surface of the opposing substrate to dissipate the charge that might otherwise build up. In some implementations, such a conductive layer can be electrically coupled to the shutter common interconnect 816 of the control matrix 800 (as shown in FIG. 3A) to help keep the shutters 807 and the conductive layer at a common potential.

Shutter assemblies employing control matrices similar to the control matrix 860 of FIG. 3B bear additional risk of shutter stiction to an opposing substrate. The risk to such shutter assemblies, cannot, however, be mitigated by use of a similar substantially continuous conductive layer being deposited on the opposing substrate. In using a control matrix similar to the control matrix 860, shutters are driven to different voltages at different times. Thus at any given time, if the opposing substrate were kept at a common potential, some shutters would experience little electrostatic force, while others would experience large electrostatic forces.

Thus, to implement a display apparatus using a control matrix similar to the control matrix 860 shown in FIG. 3B, the display apparatus can incorporate a pixilated conductive layer. Such a conductive layer is divided into multiple electrically isolated regions, with each region corresponding to, and being electrically coupled to, the shutter of a vertically adjacent shutter assembly. One display apparatus architecture suitable for use with a control matrix similar to the control matrix 860 depicted in FIG. 3B is shown in FIG. 4.

FIG. 4 shows a cross-sectional view of an example display apparatus 900 incorporating flexible conductive spacers. The display apparatus 900 is built in a MEMS-up configuration. That is, an array of shutter-based display elements that includes a plurality of shutters 920 is fabricated on a transparent substrate 910 positioned towards the rear of the display apparatus 900 and faces up towards a cover sheet 940 that forms the front of the display apparatus 900. The transparent substrate 910 is coated with a light absorbing layer 912 through which rear apertures 914 corresponding to the overlying shutters 920 are formed. The transparent substrate 910 is positioned in front of a backlight 950. Light emitted by the backlight 950 passes through the apertures 914 to be modulated by the shutters 920.

The display elements include anchors 904 configured to support one or more electrodes, such as drive electrodes 924 and load electrodes 926 that make up the actuators of the display apparatus 900.

The display apparatus 900 also includes a cover sheet 940 on which a conductive layer 922 is formed. The conductive layer 922 is pixilated to form a plurality of electrically isolated conductive regions that correspond to respective ones of the underlying shutters 920. Each of the electrically isolated conductive regions formed on the cover sheet 940 is vertically adjacent to an underlying shutter 920 and is electrically coupled thereto. The cover sheet 940 further includes a light blocking layer 942 through which a plurality of front apertures 944 are formed. The front apertures 944 are aligned with the rear apertures 914 formed through the light absorbing layer 912 on the transparent substrate 910 opposite the cover sheet 940.

The cover sheet 940 can be a flexible substrate (such as glass, plastic, polyethylene terephthalate (PET), polyethylene napthalate (PEN), or polyimide) that is capable of deforming from a relaxed state towards the transparent substrate 910 when the fluid contained between the cover sheet 940 and the transparent substrate 910 contracts at lower temperatures, or in response to an external pressure, such as a user's touch. At normal or high temperatures, the cover sheet 940 is capable of returning to its relaxed state. Deformation in response to temperature changes helps prevent bubble formation within the display apparatus 900 at low temperatures, but poses challenges with respect to maintaining an electrical connection between the electrically isolated regions of the conductive layer 922 and their corresponding shutters 920. Specifically, to accommodate the deformation of the cover sheet 940, the display apparatus must include an electrical connection that can likewise deform vertically with the cover sheet 940.

Accordingly, the cover sheet 940 is supported over the transparent substrate 910 by flexible conductive spacers 902a-902d (generally “flexible conductive spacers 902”). The flexible conductive spacers 902 can be made from a polymer and coated with an electrically conductive layer. The flexible conductive spacers 902 are formed on the transparent substrate 910 and electrically couple a corresponding shutter 920 to a corresponding conductive region on the cover sheet 940. In some implementations, the flexible conductive spacers 902 can be sized to be slightly taller than the cell gap, i.e., the distance between the cover sheet 940 and the transparent substrate 910 at their edges. The flexible conductive spacers 902 are configured to be compressible such that they can be compressed by the cover sheet 940 when the cover sheet 940 deforms towards the transparent substrate 910 and then return to their original states when the cover sheet 940 returns to its relaxed state. In this way, each of the flexible conductive spacers 902 maintains an electrical connection between a conductive region on the cover sheet 940 and a corresponding shutter 920, even as the cover sheet deforms and relaxes. In some implementations, the flexible conductive spacers 902 can be taller than the cell gap by about 0.5 to about 5.0 micrometers (microns).

FIG. 4 shows the display apparatus 900 can be operated in a low temperature environment, for example at around 0° C. At such temperatures, the cover sheet 940 can deform towards the transparent substrate 910, as is depicted in FIG. 4. Due to the deformation, the flexible conductive spacers 902b and 902c are more compressed than the flexible conductive spacers 902a and 902d. Under higher temperature conditions, such as room temperature, the cover sheet 940 can return to its relaxed state. As the cover sheet 940 returns to its relaxed state, the flexible conductive spacers 902 also return to their original states, while maintaining an electrical connection with a corresponding conductive region of the light blocking layer 942 formed on the cover sheet 940.

The distance between the front apertures 944 and their corresponding rear apertures 914 can affect display characteristics of the display apparatus. In particular, a larger distance between the front apertures 944 and corresponding rear apertures 914 can adversely affect the viewing angle of the display. Although reducing the distance between the front apertures and corresponding rear apertures is desirable, doing so is challenging due to the deformable nature of the coversheet 940 on which the front light blocking layer 942 is formed. Specifically, the distance is set to be large enough such that the cover sheet 940 can deform without coming into contact with the shutters 920, anchors 904 or drive or load electrodes 924 and 926. While this maintains the physical integrity of the display, it is non-ideal with regards to the optical performance of the display.

Instead of using flexible conductive spacers, such as the flexible conductive spacers 902 shown in FIG. 4, to maintain an electrical connection between the conductive regions formed on the cover sheet and the underlying shutters, a pixilated conductive layer can be positioned between the shutters of a display apparatus and a cover sheet. This layer can be fabricated on the same substrate as the shutter assemblies that include the shutters. By relocating the conductive layer off of the coversheet, the coversheet can deform freely without impacting the electrical connection between the conductive layer and the shutters.

In some implementations, this intervening conductive layer takes the form of or be included as part of an elevated aperture layer (EAL). An EAL includes apertures formed through it across its surface corresponding to rear apertures formed in a rear light blocking layer deposited on the underlying substrate. The EAL can be pixilated to form electrically isolated conductive regions similar to the pixilated conductive layer formed on the cover sheet 940 shown in FIG. 4. Use of an EAL can both obviate the need to maintain an electrical connection with surfaces deposited on the deformable cover sheet and position a front set of apertures closer to the rear set of apertures, improving image quality.

Relocating the front apertures to an EAL, which does not need to deform, enables the front apertures to be located closer to the rear apertures, thereby enhancing a display's viewing angle characteristics. Moreover, since the front apertures are no longer a part of the cover sheet, the cover sheet can be spaced further away from the transparent substrate without affecting the contrast ratio or viewing angle of the display.

FIG. 5A shows a cross-sectional view of an example display apparatus 1000 incorporating an EAL 1030. The display apparatus 1000 is built in a MEMS-up configuration. That is, an array of shutter-based display elements is fabricated on a transparent substrate 1002 positioned towards the rear of the display apparatus 1000. FIG. 5A shows one such shutter-based display element, i.e., a shutter assembly 1001. The transparent substrate 1002 is coated with a light blocking layer 1004 through which rear apertures 1006 are formed. The light blocking layer 1004 can include a reflective layer facing a backlight 1015 is positioned behind the substrate 1002 and a light absorbing layer facing away from the backlight 1015. Light emitted by the backlight 1015 passes through the rear apertures 1006 to be modulated by the shutter assemblies 1001.

Each of the shutter assemblies 1001 includes a shutter 1020. As shown in FIG. 5A, the shutter 1020 is a dual-actuated shutter. That is, the shutter 1020 can be driven in one direction by a first actuator 1018 and driven to a second direction by a second actuator 1019. The first actuator 1018 includes a first drive electrode 1024a and a first load electrode 1026a that together are configured to drive the shutter 1020 in a first direction. The second actuator 1019 includes a second drive electrode 1024b and a second load electrode 1026b that together are configured to drive the shutter 1020 in a second direction opposite the first direction.

A plurality of anchors 1040 are built on the transparent substrate 1002 and support the shutter assemblies 1001 over the transparent substrate 1002. The anchors 1040 also support the EAL 1030 over the shutter assemblies. As such, the shutter assemblies are disposed between the EAL 1030 and the transparent substrate 1002. In some implementations, the EAL 1030 is separated from the underlying shutter assemblies by a distance of about 2 to about 5 microns.

The EAL 1030 includes a plurality of aperture layer apertures 1036 that are formed through the EAL 1030. The aperture layer apertures 1036 are aligned with the rear apertures 1006 formed through the light blocking layer 1004. The EAL 1030 can include one or more layers of material. As shown in FIG. 5A, the EAL 1030 includes a layer of conductive material 1034 and a light absorbing layer 1032 formed on top of the layer of conductive material 1034. The light absorbing layer 1032 can be an electrically insulating material, such as a dielectric stack configured to cause destructive interference or an insulating polymer matrix, which in some implementations incorporates light absorbing particles. In some implementations, the insulating polymer matrix can be mixed with light absorbing particles. In some implementations, the layer of conductive material 1034 can be pixilated to form a plurality of electrically isolated conductive regions. Each of the electrically isolated conductive regions can correspond to an underlying shutter assembly and can be electrically coupled to underlying shutter 1020 via the anchor 1040. As such, the shutter 1020 and the corresponding electrically isolated conductive region formed on the EAL 1030 can be maintained at the same voltage potential. Maintaining the isolated conductive regions and their respective corresponding shutters at a common voltage enables the display apparatus 1000 to include a control matrix, such as the control matrix 860 depicted in FIG. 3B, in which different voltages are applied to different shutters, without substantially increasing the risk of shutter stiction. In some implementations, the conductive material is or can include aluminum (Al), copper (Cu), nickel (Ni), chromium (Cr), molybdenum (Mo), titanium (Ti), tantalum (Ta), niobium (Nb), neodymium (Nd), or alloys thereof, or semiconducting materials such as diamond-like carbon, silicon (Si), germanium (Ge), gallium arsenide (GaAs), cadmium telluride (CdTe) or alloys thereof. In some implementations employing semiconductor layers, the semiconductors are doped with impurities such as phosphorus (P), arsenic (As), boron (B), or Al.

The EAL 1030 faces up towards a cover sheet 1008 that forms the front of the display apparatus 1000. The cover sheet 1008 can be a glass, plastic or other suitable substantially transparent substrate that is coated with one or more layers of anti-reflective and/or light absorbing material. In some implementations, a light blocking layer 1010 is coated on a surface of the cover sheet 1008 facing the EAL 1030. In some implementations, the light blocking layer 1010 is formed from a light absorbing material. A plurality of front apertures 1012 are formed through the light blocking layer 1010. The front apertures 1012 are aligned with the aperture layer apertures 1036 and the rear apertures 1006. In this way, light from the backlight 1015 that passes through the aperture layer apertures 1036 formed in the EAL 1030 also can pass through the overlying front apertures 1012 to form an image.

The cover sheet 1008 is supported over the transparent substrate 1002 via an edge seal (not depicted) formed along the perimeter of the display apparatus 1000. The edge seal is configured to seal a fluid between the cover sheet 1008 and the transparent substrate 1002 of the display apparatus 1000. In some implementations, the cover sheet 1008 also can be supported by spacers (not depicted) that are formed on the transparent substrate 1002. The spacers may be configured to allow the cover sheet 1008 to deform towards the EAL 1030. Further, the spacers may be tall enough to prevent the cover sheet from deforming enough to come into contact with the aperture layer. In this way, damage to the EAL 1030 caused by the cover sheet 1008 impacting the EAL 1030 can be avoided. In some implementations, the cover sheet 1008 is separated from the EAL by a gap of at least about 20 microns when the cover sheet 1008 is in the relaxed state. In some other implementations, the gap is between about 2 microns and about 30 microns. In this way, even if the cover sheet 1008 is caused to deform due to the contraction of the fluid contained in the display apparatus 1000 or the application of external pressure, the cover sheet 1008 will have a decreased likelihood of coming in to contact with the EAL 1030.

FIG. 5B shows a top view of an example portion of the EAL 1030 shown in FIG. 5A. FIG. 5B shows the light absorbing layer 1032 and the layer of conductive material 1034. The layer of conductive material 1034 is shown in broken lines as it is positioned below the light absorbing layer 1032. The layer of conductive material 1034 is pixilated to form a plurality of electrically isolated conductive regions 1050a-1050n (generally referred to as conductive regions 1050). Each of the conductive regions 1050 corresponds to a particular shutter assembly 1001 of the display apparatus 1000. A set of aperture layer apertures 1036 can be formed through the light absorbing layer 1032 such that each aperture layer aperture 1036 aligns with a respective rear aperture 1006 formed in the rear light blocking layer 1004. In some implementations, for example when the layer of conductive material 1034 is formed from a non-transparent material, the aperture layer apertures 1036 are formed through the light absorbing layer 1032 and through the layer of conductive material 1034. Further, each of the conductive regions 1050 is supported by four anchors 1040 at about the corners of the respective conductive region 1050. In some other implementations, the EAL 1030 can be supported by fewer or more anchors 1040 per conductive region 1050.

In some implementations, the display apparatus 1000 can include slotted shutters, such as the shutter 202 shown in FIG. 2 In some such implementations, the EAL 1030 may include multiple aperture layer apertures for each of the slotted shutters.

In some other implementations, the EAL 1030 can be implemented using a single layer of light blocking conductive material. In such implementations, each electrically isolated conductive region 1050 can stand above its corresponding shutter assembly 1001 physically separated from its adjacent conductive regions 1050. By way of example, from a top view, the EAL 1030 may appear similar to an array of tables, with the layer of conductive material 1034 forming the table tops, and the anchors 1040 forming the legs of the respective tables.

As described above, incorporating an EAL is particularly beneficial in display apparatus that utilize control matrices similar to the control matrix 860 of FIG. 3B in which drive voltages are selectively applied to display apparatus shutters. Use of an EAL still provides a number of advantages for display apparatus that incorporate control matrices in which all shutters are maintained at a common voltage. For example, in some such implementations, the EAL need not be pixilated, and the entire EAL can be maintained at the same common voltage as the shutters.

FIG. 6A shows a cross-sectional view of an example display apparatus 1100 incorporating an EAL 1130. The display apparatus 1100 is substantially similar to the display apparatus 1000 shown in FIG. 5A except that the EAL 1130 of the display apparatus 1100 is not pixilated to form electrically isolated conductive regions, such as the electrically isolated conductive regions 1050 shown in FIG. 5B.

The EAL 1130 defines a plurality of aperture layer apertures 1136 that correspond to underlying rear apertures 1006 formed through a light blocking layer 1004 on a transparent substrate 1002. The EAL 1130 can include a layer of light blocking material such that light from the backlight 1015 directed towards the aperture layer aperture 1136 passes through, while light that inadvertently bypasses modulation by the shutter 1020 or that rebounds off the shutter 1020 is blocked. As a result, only light that is modulated by the shutter and passes through the aperture layer apertures 1036 contributes to an image, enhancing the contrast ratio of the display apparatus 1100.

FIG. 6B shows a top view of an example portion of the EAL 1130 shown in FIG. 6A. As described above, the EAL 1130 is similar to the EAL 1030 in FIG. 5A except that the EAL 1130 is not pixelated. That is, the EAL 1130 does not include electrically isolated conductive regions.

FIGS. 6C-6E show top views of portions of additional example EALs. FIG. 6C shows a top view of a portion of an example EAL 1150. The EAL 1150 is substantially similar to the EAL 1130 except that the EAL 1150 includes a plurality of etch holes 1158a-1158n (generally etch holes 1158) formed through the EAL 1150. The etch holes 1158 are formed during the fabrication process of the display apparatus to facilitate the removal of mold material that is used to form the shutter assemblies and the EAL 1150. In particular, the etch holes 1158 are formed to allow a fluid etchant (such as a gas, liquid, or plasma) to more readily reach, react with, and remove the mold material used to form the display elements and the EAL. Removing the mold material from a display apparatus that includes an EAL can be challenging because the EAL covers most of the mold material, with little mold material being directly exposed. This makes it difficult for the etchant to reach the mold material and can significantly increase the amount of time needed to release the underlying shutter assemblies. In addition to requiring additional time, prolonged exposure to the etchant has the potential for damaging components of the display apparatus that are intended to survive the release process. Additional details related to the release process used for manufacturing display apparatus incorporating EALs is provided below in relation to stage 1410 shown in FIG. 9.

The etch holes 1158 may be strategically formed at locations of the EAL that fall outside a light blocking region 1155 associated with each of the shutter assemblies included in the display apparatus 1100. The light blocking region 1155 is defined by an area on a rear surface of the EAL within which substantially all light from the backlight that passes through a corresponding rear aperture, if not passed through an aperture layer aperture 1136 or blocked or absorbed by the shutter 1020, will contact the rear surface of the EAL. Ideally, all light passing through the rear aperture layer either passes by or through the shutter 1020 (in the transmissive state) or is absorbed by the shutter 1020 (in the light blocking state). In reality though, in the closed state, some light rebounds off of the rear surface of shutter 1020 and can even rebound again off of the light blocking layer 1004. Some light also may scatter off of the edges of the shutter. Similarly, in the transmissive state, some light may rebound off of or be scattered by various surfaces of the shutter 1020. As a result, maintaining a relatively large light blocking region 1155 can help maintain higher contrast ratios. If defined to be relatively large, little to no light from the backlight impinges the rear surface of the EAL 1150 outside of the light blocking region 1155. As such, it is relatively safe to form the etch holes 1158 in areas that lie outside of the light blocking region without meaningfully jeopardizing the display's contrast ratio.

The etch holes 1158 can come in various shapes and sizes. In some implementations, the etch holes 1158 are circular holes having a diameter of about 5 to about 30 microns.

Conceptually, the EAL 1150 can be thought of as including a plurality of aperture layer sections 1151a-n (generally aperture layer sections 1151), each of which corresponds to a respective display element. The aperture layer sections 1151 can share boundaries with adjacent aperture layer sections 1151. In some implementations, the etch holes 1158 are formed outside the light blocking region 1155 near the boundaries of the aperture layer sections.

FIG. 6D shows a top view of a portion of another example EAL 1160. The EAL 1160 is substantially similar to the EAL 1150 shown in FIG. 6C except that the EAL 1160 defines a plurality of etch holes 1168a-1168n (generally etch holes 1168) formed at the intersections of aperture layer sections 1161. That is, the EAL 1160 includes fewer, larger etch holes 1168, in contrast to the EAL 1150 shown in FIG. 6C, which more, smaller etch holes 1158.

FIG. 6E shows a top view of a portion of another example EAL 1170. The EAL 1170 is substantially similar to the EAL 1150 shown in FIG. 6B except that the EAL 1170 FIG. 6D defines a plurality of etch holes 1178a-1178n (generally etch holes 1178) that are sized and shaped differently from the circular etch holes 1158 shown in FIG. 6B. In particular, the etch holes 1178 are rectangular and have a length that is greater than or about equal to half the length of the corresponding aperture layer sections 1171 in which the etch hole 1178 is formed. Similar to the etch holes 1158 of the EAL 1150 shown in FIG. 6B, the etch holes 1178 FIG. 6E are also formed outside the light blocking region of the EAL 1170.

FIG. 7 shows a cross-sectional view of an example display apparatus 1200 incorporating an EAL 1230. The display apparatus 1200 is substantially similar to the display apparatus 1100 shown in FIG. 6A in that the display apparatus 1200 includes an array of shutter-based display elements that includes a plurality of shutters 1220 fabricated on a transparent substrate 1202 positioned towards the rear of the display apparatus 1200. The transparent substrate 1202 is coated with a light blocking layer 1204 through which rear apertures 1206 are formed. The transparent substrate 1202 is positioned in front of a backlight 1215. Light emitted by the backlight 1215 passes through the rear apertures 1206 to be modulated by the shutters 1220.

The display apparatus 1200 also includes the EAL 1230, which is similar to the EAL 1130 shown in FIG. 6A. The EAL 1230 includes a plurality of aperture layer apertures 1236 that are formed through the EAL 1230 and correspond to respective underlying shutters 1220. The EAL 1230 is formed on the transparent substrate 1202 and supported over the transparent substrate 1202 and the shutters 1220.

The display apparatus 1200 differs from the display apparatus 1100, however, in that the EAL 1230 is supported over the transparent substrate 1202 using anchors 1250 that do not support the underlying shutter assemblies. Rather, the shutter assemblies are supported by anchors 1225 that are separate from the anchors 1250.

The display apparatus shown in FIGS. 5A-17 incorporate an EAL in a MEMS-up configuration. Display apparatus in the MEMS-down configuration also can incorporate a similar EAL.

FIG. 8 shows a cross-sectional view of a portion of an example MEMS down display apparatus. The display apparatus 1300 includes a substrate 1302 having a reflecting aperture layer 1304 through which apertures 1306 are formed. In some implementations, a light absorbing layer is deposited on top of the reflecting aperture layer 1304. Shutter assemblies 1320 are disposed on a front substrate 1310 separate from the substrate 1302 on which the reflective aperture layer 1304 is formed. The substrate 1302 on which the reflective aperture layer 1304 is formed, defining a plurality of apertures 1306, is also referred to herein as the aperture plate. In the MEMS-down configuration, the front substrate 1310 that carries the MEMS-based shutter assemblies 1320 takes the place of the cover sheet 1008 of the display apparatus 1000 shown in FIG. 5A and is oriented such that the MEMS-based shutter assemblies 1320 are positioned on a rear surface 1312 of the front substrate 1310, that is, the surface that faces away from the viewer and toward a backlight 1315. A light blocking layer 1316 can be formed on the rear surface 1312 of the front substrate 1310. In some implementations, the light blocking layer 1316 is formed from a light absorbing, or dark, metal. In some other implementations, the light blocking layer is formed from a non-metal light absorbing material. A plurality of apertures 1318 are formed through the light blocking layer 1316.

The MEMS-based shutter assemblies 1320 are positioned directly opposite to, and across a gap from, the reflective aperture layer 1304. The shutter assemblies 1320 are supported from the front substrate 1310 by a plurality of anchors 1340.

The anchors 1340 also can be configured to support an EAL 1330. The EAL defines a plurality of aperture layer apertures 1336 that are aligned with the apertures 1318 formed through the light blocking layer 1316 and the apertures 1306 formed through the light reflecting aperture layer 1304. Similar to the EAL 1030 shown in FIG. 5A, the EAL 1330 also can be pixilated to form electrically isolated conductive regions. In some implementations, the EAL 1330, other than with respect to its position on the substrate 1319, can be structurally substantially similar to the EAL 1130 shown in FIG. 6A.

In some other implementations, the reflecting aperture layer 1304 is deposited on the rear surface of the EAL 1330 instead of on the substrate 1302. In some such implementations, the substrate 1302 can be coupled to the front substrate 1310 substantially without alignment. In some other of such implementations, for example, in some implementations in which etch holes similar to the etch holes 1158, 1168 and 1178 shown in FIGS. 6C-6E, respectively, are formed through the EAL, a reflective aperture layer may still be applied on the substrate 1302. However, this reflective aperture layer need only block light that would pass through the etch holes, and therefore can include relatively large apertures. Such large apertures would result in significant increases in the alignment tolerance between the substrates 1302 and the 1310.

FIG. 9 shows a flow diagram of an example process 1400 for manufacturing a display apparatus. The display apparatus can be formed on a substrate and includes an anchor that supports an EAL that is formed above a shutter assembly that is also supported by the anchor. In brief overview, the process 1400 includes forming a first mold portion on a substrate (stage 1401). A second mold portion is formed over the first mold portion (stage 1402). Shutter assemblies are then formed using the mold (stage 1404). A third mold portion is then formed over the shutter assemblies and the first and second mold portions (stage 1406), followed by the formation of an EAL (stage 1408). The shutter assemblies and the EAL are then released (stage 1410). Each of these process stages as well as further aspects of the manufacturing process 1400 are described below in relation to FIGS. 10A-10I and FIGS. 11A-11D. In some implementations, an additional processing stage is carried out between the formation of the EAL (stage 1408) and the release of the EAL and the shutter assemblies (stage 1410). More particularly, as discussed further in relation to FIGS. 16 and 17, in some implementations, one or more electrical interconnects are formed on top of the EAL (stage 1409) before the release stage (stage 1410).

FIGS. 10A-10I show cross-sectional views of stages of construction of an example display apparatus according to the manufacturing process 1400 shown in FIG. 9. This process yields a display apparatus formed on a substrate and that includes an anchor that supports an integrated EAL that is formed above a shutter assembly also supported by the anchor. In the process shown in FIGS. 10A-10I, the display apparatus is formed on a mold made from a sacrificial material.

Referring to FIGS. 9 and 10A-10I, the process 1400 for forming a display apparatus begins, as shown in FIG. 10A, with the formation of a first mold portion on top of a substrate (stage 1401). The first mold portion is formed by depositing and patterning of a first sacrificial material 1504 on top of a light blocking layer 1503 of an underlying substrate 1502. The first layer of sacrificial material 1504 can be or can include polyimide, polyamide, fluoropolymer, benzocyclobutene, polyphenylquinoxylene, parylene, polynorbornene, polyvinyl acetate, polyvinyl ethylene, and phenolic or novolac resins, or any of the other materials identified herein as suitable for use as a sacrificial material. Depending on the material selected for use as the first layer of sacrificial material 1504, the first layer of sacrificial material 1504 can be patterned using a variety of photolithographic techniques and processes such as by direct photo-patterning (for photosensitive sacrificial materials) or chemical or plasma etching through a mask formed from a photolithographically patterned resist.

Additional layers, including layers of material forming a display control matrix may be deposited below the light blocking layer 1503 and/or between the light blocking layer 1503 and the first sacrificial material 1504. The light blocking layer 1503 defines a plurality of rear apertures 1505. The pattern defined in the first sacrificial material 1504 creates recesses 1506 within which anchors for shutter assemblies will eventually be formed.

The process of forming the display apparatus continues with forming a second mold portion (stage 1402). The second mold portion is formed from depositing and patterning a second sacrificial material 1508 on top of the first mold portion formed from the first sacrificial material 1504. The second sacrificial material can be the same type of material as the first sacrificial material 1504.

FIG. 10B shows the shape of a mold 1599, including the first and second mold portions, after the patterning of the second sacrificial material 1508. The second sacrificial material 1508 is patterned to form a recess 1510 to expose the recess 1506 formed in the first sacrificial material 1504. The recess 1510 is wider than the recess 1506 such that a step like structure is formed in the mold 1599. The mold 1599 also includes the first sacrificial material 1504 with its previously defined recesses 1506.

The process of forming the display apparatus continues with the formation of shutter assemblies using the mold (stage 1404), as shown in FIGS. 10C and 10D. The shutter assemblies are formed by depositing structural materials 1516 onto the exposed surfaces of the mold 1599, as shown in FIG. 10C, followed by patterning the structural material 1516, resulting in structure shown in FIG. 10D. The structural material 1516 can include one or more layers including mechanical as well conductive layers. Suitable structural materials 1516 include metals such as Al, Cu, Ni, Cr, Mo, Ti, Ta, Nb, Nd, or alloys thereof; dielectric materials such as aluminum oxide (Al₂O₃), silicon oxide (SiO₂), tantalum pentoxide (Ta₂O₅), or silicon nitride (Si₃N₄); or semiconducting materials such as diamond-like carbon, Si, Ge, GaAs, CdTe or alloys thereof. In some implementations, the structural material 1516 includes a stack of materials. For example, a layer of conductive structural material may be deposited between two non-conductive layers. In some implementations, a non-conductive layer is deposited between two conductive layers. In some implementations, such a “sandwich” structure helps to ensure that stresses remaining after deposition and/or stresses that are imposed by temperature variations will not act cause bending, warping or other deformation of the structural material 1516. The structural material 1516 is deposited to a thickness of less than about 2 microns. In some implementations, the structural material 1516 is deposited to have a thickness of less than about 1.5 microns.

After deposition, the structural material 1516 (which may be a composite of several materials as described above) is patterned, as shown in FIG. 10D. First, a photoresist mask is deposited on the structural material 1516. The photoresist is then patterned. The pattern developed into the photoresist is designed such that structural material 1516, after a subsequent etch stage, remains to form a shutter 1528, anchors 1525, and drive and load beams 1526 and 1527 of two opposing actuators. The etch of the structural material 1516 can be an anisotropic etch and can carried out in a plasma atmosphere with a voltage bias applied to the substrate, or to an electrode in proximity to the substrate.

Once the shutter assemblies of the display apparatus are formed, the manufacturing process continues with fabricating the EAL of the display. The process of forming the EAL begins with the formation of a third mold portion on top of the shutter assemblies (stage 1406). The third mold portion is formed from a third sacrificial material layer 1530. FIG. 10E shows the shape of the mold 1599 (including the first, second, and third mold portions) that is created after depositing the third sacrificial material layer 1530. FIG. 10F shows the shape of the mold 1599 that is created after patterning the third sacrificial material layer 1530. In particular, the mold 1599 shown in FIG. 10F includes recesses 1532 where a portion of the anchor will be formed for supporting the EAL over the underlying shutter assemblies. The third sacrificial material layer 1530 can be or include any of the sacrificial materials disclosed herein.

The EAL is then formed, as shown in FIG. 10G (stage 1408). First one or more layers of aperture layer material 1540 are deposited on the mold 1599. In some implementations, the aperture layer material can be or can include one or more layers of a conductive material, such as a metal or conductive oxide, or a semiconductor. In some implementations, the aperture layer can be made of or include a polymer that is non-conductive. Some examples of suitable materials were provided above with respect to FIG. 5A.

Stage 1408 continues with etching the deposited aperture layer material 1540 (shown in FIG. 10G), resulting in an EAL 1541, as shown in FIG. 10H. The etch of the aperture layer material 1540 can be an anisotropic etch and can be carried out in a plasma atmosphere with a voltage bias applied to the substrate, or to an electrode in proximity to the substrate. In some implementations, the application of the anisotropic etch is performed in a manner similar to the anisotropic etch described with respect to FIG. 10D. In some other implementations, depending on the type of material used to form the aperture layer, the aperture layer may be patterned and etched using other techniques. Upon applying the etch, an aperture layer aperture 1542 is formed in a portion of the EAL 1541 aligned with an aperture 1505 formed through the light blocking layer 1503.

The process of forming the display apparatus 1500 is completed with the removal of the mold 1599 (stage 1410). The result, shown in FIG. 10I, includes anchors 1525 that support the EAL 1541 over the underlying shutter assemblies that include shutters 1528 also supported by the anchors 1525. The anchors 1525 are formed from portions of the layers of structural material 1516 and aperture layer material 1540 left behind after the above-described patterning stages.

In some implementations, the mold is removed using standard MEMS release methodologies, including, for example, exposing the mold to an oxygen plasma, wet chemical etching, or vapor phase etching. However, as the number of sacrificial layers used to form the mold increase to create an EAL, the removal of the sacrificial materials can become a challenge, since a large volume of material may need to be removed. Moreover, the addition of the EAL substantially obstructs direct access to the material by a release agent. As a result, the release process can take longer. While most, if not all, of the structural materials selected for use in a final display assembly are selected to be resistant to the release agent, prolonged exposure to such an agent may still cause damage to various materials. Accordingly, in some other implementations, a variety of alternative release techniques may be employed, some of which are further described below.

In some implementations, the challenge of removing sacrificial materials is addressed by forming etch holes through the EAL. Etch holes increase the access a release agent has to the underlying sacrificial material. As described above with respect to FIGS. 6C-6E, the etch holes can be formed in an area that lies outside the light blocking region of the EAL, such as the light blocking region 1155 shown in FIG. 6C. In some implementations, the size of the etch holes is sufficiently large to allow a fluid (such as a liquid, gas, or plasma) etchant to remove the sacrificial material that forms the mold, while remaining sufficiently small that it does not adversely affect optical performance.

In some other implementations, a sacrificial material is used that is capable of decomposing by sublimating from solid to gas, without requiring the use of a chemical etchant. In some such implementations, the sacrificial material can sublimate by baking a portion of the display apparatus that is formed using a mold. In some implementations, the sacrificial material can be composed of or include norbornene or a norbornene derivative. In some such implementations employing norbornene or a norbornene derivatives in the sacrificial mold, the portion of the display apparatus that includes the shutter assemblies, the EAL and their supporting mold can be baked at temperatures in a range of about 400° C. for about 1 hours. In some other implementations, the sacrificial material can be composed of or can include any other sacrificial material that sublimates at temperatures below about 500° C., such as polycarbonates, which can decompose at temperatures between about 200-300° C. (or at lower temperatures in the presence of an acid.

In some other implementations, a multi-phase release process is employed. For example, in some such implementations, the multi-phase release process includes a liquid etch followed by a dry plasma etch. In general, even though the structural and electrical components of the display apparatus are selected to be resistant to the etching agents used to effectuate the release process, prolonged exposure to certain etchants, particularly, dry plasma etchants, can still damage such components. Thus, it is desirable to limit the time the display apparatus is exposed to a dry plasma etch. Liquid etchants, however, tend to be less effective at fully releasing a display apparatus. Employing a multi-phase release process effectively addresses both concerns. First, a liquid etch removes portions of the mold directly accessible through the aperture layer apertures and any etch holes formed in the EAL, creating cavities under the EAL in the mold material. Thereafter, a dry plasma etch is applied. The initial formation of the cavities increases the surface area the dry plasma etch can interact with, expediting the release process, thereby limiting the amount of time the display apparatus is exposed to the plasma.

As described herein, the manufacturing process 1400 is carried out in conjunction with the formation of shutter-based light modulators. In some other implementations, the process for manufacturing an EAL can be carried out with the formation of other types of display elements, including light emitters, such as OLEDs, or other light modulators.

FIG. 11A shows a cross-sectional view of an example display apparatus 1600 incorporating an encapsulated EAL. The display apparatus 1600 is substantially similar to the display apparatus 1500 shown in FIG. 10I in that the display apparatus 1600 also includes a display apparatus that includes anchors 1640 supporting an EAL 1630 over underlying shutters 1528, which are also supported by the anchors 1640. However, the display apparatus 1600 differs from the display apparatus 1500 shown in FIG. 10I in that the EAL 1630 includes a layer of polymer material 1652 that is encapsulated by structural material 1656. In some implementations, the structural material 1656 may be metal. By encapsulating the polymer material 1652 with structural material 1656, the EAL 1630 is structurally resilient to external forces. As such, the EAL 1630 can serve as a barrier to protect underlying shutter assemblies. Such additional resilience may be particularly desirable in products that suffer increased levels of abuse, such as devices geared for children, the construction industry, and the military, or other users of ruggedized equipment.

FIGS. 11B-11D show cross-sectional views of stages of construction of the example display apparatus 1600 shown in FIG. 11A. The manufacturing process used to form the display apparatus 1600 incorporating an encapsulated EAL begins with forming a shutter assembly and the EAL in a manner similar to that described above with respect to FIGS. 9 and 10A-10I. After depositing and patterning the aperture layer material 1540 as described above with respect to stage 1408 of the process 1400, shown in FIG. 9 and FIGS. 10G and 10H, the process of forming the encapsulated EAL continues with the deposition of a polymer material 1652 on top of the EAL 1541, as shown in FIG. 11B. The deposited polymer material 1652 is then patterned to form an opening 1654 aligned with the aperture 1542 formed in the aperture layer material 1540. The opening 1654 is made wide enough to expose a portion of the underlying aperture layer material 1540 surrounding aperture 1542. The result of this process stage is shown in FIG. 11C.

The process of forming the EAL continues with the deposition and patterning of a second layer of aperture layer material 1656 on top of the patterned polymer material 1652, as shown in FIG. 11D. The second layer of aperture layer material 1656 can be the same material as the first aperture layer material 1540, or it can be some other structural material suitable for encapsulating the polymer material 1652. In some implementations, the second layer of aperture layer material 1656 can be patterned by applying an anisotropic etch. As shown in FIG. 11D, the polymer material 1652 remains encapsulated by the second layer of aperture layer material 1656.

The process of forming the EAL and the shutter assembly is completed with the removal of the remainder of the mold formed from the first, second, and third layers of sacrificial material 1504, 1508, and 1530. The result is shown in FIG. 11A. The process of removing sacrificial material is similar to that described above with respect to FIG. 10I or FIG. 19. The anchors 1640 support the shutter assembly over the underlying substrate 1502 and support the encapsulated aperture layer 1630 over the underlying shutter assembly.

Added EAL resilience can alternatively be obtained by introducing stiffening ribs into the surface of the EAL. The inclusion of stiffening ribs in the EAL can be in addition to, or instead of the EAL utilizing the encapsulation of a polymer layer.

FIG. 12A shows a cross-sectional view of an example display apparatus 1700 incorporating a ribbed EAL 1740. The display apparatus 1700 is similar to the display apparatus 1500 shown in FIG. 10I in that the display apparatus 1700 also includes an EAL 1740 that is supported over a substrate 1702 and underlying shutters 1528 by a plurality of anchors 1725. However, the display apparatus 1700 differs from the display apparatus 1500 in that the EAL 1740 includes ribs 1744 for strengthening the EAL 1740. By forming ribs within the EAL 1740, the EAL 1740 can become more structurally resilient to external forces. As such, the EAL 1740 can serve as a barrier to protect the display element, including the shutters 1528.

FIGS. 12B-12E show cross-sectional views of stages of construction of the example display apparatus 1700 shown in FIG. 12A. The display apparatus 1700 includes anchors 1725 for supporting a ribbed EAL 1740 over a plurality of shutters 1528 that are also supported by the anchors 1725. The manufacturing process used to form such a display apparatus begins with forming a shutter assembly and an EAL in a manner similar to that described above with respect to FIGS. 10A-10I. After depositing and patterning the third sacrificial material layer 1530 as described above with respect to FIG. 10G, however, the process of forming the ribbed EAL 1740 continues with the deposition of a fourth sacrificial layer 1752 as shown in FIG. 12B. The fourth sacrificial layer 1752 is then patterned to form a plurality of recesses 1756 for forming the ribs that will eventually be formed in the elevated aperture. The shape of a mold 1799 that is created after patterning of the fourth sacrificial layer 1752 is shown in FIG. 12C. The mold 1799 includes the first sacrificial material 1504, the second sacrificial material 1508, the patterned layer of structural material 1516, the third sacrificial material layer 1530 and the fourth sacrificial layer 1752.

The process of forming the ribbed EAL 1740 continues with the deposition of a layer of aperture layer material 1780 onto all of the exposed surfaces of the mold 1799. Upon depositing the layer of aperture layer material 1780, the layer of aperture layer material 1780 is patterned to form openings that serves as the aperture layer apertures (or “EAL apertures”) 1742, as shown in FIG. 12D.

The process of forming the display apparatus that includes the ribbed EAL 1740 is completed with the removal of the remainder of the mold 1799, i.e., the remainder of the first, second, third, and fourth layers of sacrificial material 1504, 1508, 1530, and 1752. The process of removing the mold 1799 is similar to that described with respect to FIG. 10I. The resulting display apparatus 1700 is shown in FIG. 12A.

FIG. 12E shows a cross-sectional view of an example display apparatus 1760 incorporating an EAL 1785 having anti-stiction bumps. The display apparatus 1760 is substantially similar to the display apparatus 1700 shown in FIG. 12A but differs from the EAL 1740 in that the EAL 1785 includes a plurality of anti-stiction bumps in regions where the ribs 1744 of the EAL 1740 are formed.

The anti-stiction bumps can be formed using a fabrication process similar to the fabrication process used to fabricate the display apparatus 1700. When patterning the layer of aperture layer material 1780 to form openings for the EAL apertures 1742 as shown in FIG. 12D, the layer of aperture layer material 1780 is also patterned to remove the aperture layer material that forms a base portion 1746 (shown in FIG. 12D) of the ribs 1744. What remains are the sidewalls 1748 of the ribs 1744. The bottom surfaces 1749 of the sidewalls 1748 can serve as the anti-stiction bumps. By having anti-stiction bumps formed at the bottom surface of the EAL 1785, the shutters are prevented from sticking to the EAL 1785.

FIG. 12F shows a cross sectional view of another example display apparatus 1770. The display apparatus 1770 is similar to the display apparatus 1700 shown in FIG. 12A in that it includes a ribbed EAL 1772. In contrast to the display apparatus 1700, the ribbed EAL 1772 of the display apparatus 1770 includes ribs 1774 that extend upwards away from a shutter assembly underlying the ribbed EAL 1772.

The process for fabricating the ribbed EAL 1772 is similar to the process used to fabricate the ribbed EAL 1740 of the display apparatus 1700. The only difference is in the patterning of the fourth sacrificial layer 1752 deposited on the mold 1799. In generating the ribbed EAL 1740, the majority of the fourth sacrificial layer 1752 is left as part of the mold, and recesses 1756 are formed within it to form a mold for the ribs 1744 (as shown in FIG. 12C). In contrast, in forming the EAL 1772, the majority of the fourth sacrificial layer 1752 is removed, leaving mesas over which the ribs 1774 are then formed.

FIGS. 12G-12J show plan views of example rib patterns suitable for use in the ribbed EALs 1740 and 1772 of FIGS. 12A and 12E. Each of FIGS. 12G-12J shows a set of ribs 1744 adjacent a pair of EAL apertures 1742. In FIG. 12G, the ribs 1744 extend linearly across the EAL. In FIG. 12H, the ribs 1744 surround the EAL apertures 1742. In FIG. 12I, the ribs 1744 extend across the EAL along two axes. Finally, in FIG. 12J, the ribs 1744 take the form of isolated recesses formed at periodic positions across the EAL. In some other implementations, a variety of additional rib patterns may be employed to strengthen an EAL.

In some implementations, the aperture layer apertures formed through an EAL can be configured to include light dispersion structures to increase the viewing angle of the display in which they are incorporated.

FIG. 13 shows a portion of a display apparatus 1800 incorporating an example EAL 1830 having light dispersion structures 1850. In particular, the display apparatus 1800 is substantially similar to the display apparatus 1000 shown in FIG. 5A. In contrast to the display apparatus 1000, the display apparatus 1800 includes the light dispersion structures 1850 that are formed in the elevated aperture layer apertures 1836 of the EAL 1830. In some implementations, the light dispersion structures 1850 can be transparent such that light can pass through the light dispersion structures 1850. In general, the light dispersion structures 1850 cause the light passing through the aperture layer aperture 1836 to reflect, refract or scatter, thereby increasing the angular distribution of light output by the display apparatus 1800. This increase in angular distribution can increase the viewing angle of the display apparatus 1800.

In some implementations, the light dispersion structures 1850 can be formed by depositing a layer of transparent material 1845, for example, a dielectric or a transparent conductor, such as ITO, on the exposed surfaces of the EAL 1830 and the mold on which the EAL 1830 is formed. The transparent material 1845 is then patterned such that light dispersion structures 1850 are formed within the region where the aperture layer apertures 1836 are eventually formed. In some implementations, the light dispersion structures can be made by depositing and patterning a layer of reflective material, for example, a layer of metal or semiconductor material.

FIGS. 14A-14H shows top views of portions of example EALs incorporating light dispersion structures 1950a-1950h (generally light dispersion structures 1950). Example patterns that the light dispersion structures 1950 may form include horizontal, vertical, diagonal stripes, or curved (see FIGS. 14A-14D), zig zag or chevron patterns (see FIG. 14E), circles (see FIG. 14F), triangles (see FIG. 14G), or other irregular shapes (see, for example, FIG. 14H). In some implementations, the light dispersion structures can include a combination of different types of light dispersion structures. Light passing through the elevated aperture layer apertures within which the light dispersion structures are formed can scatter differently based on the type of light dispersion structures formed within the aperture layer apertures of the EAL. For example, depending on the specific geometries and surface roughnesses of the light dispersion structures, light can refract as it passes through the interfaces between layers of material that form the light dispersion structures, or it can reflect or scatter off the edges and surfaces of the structures.

FIG. 15 shows a cross-sectional view of an example display apparatus 2000 incorporating an EAL 2030 that includes a lens structure 2010. The display apparatus 2000 is substantially similar to the display apparatus shown in FIG. 5 except that the display apparatus 2000 includes the lens structure 2010 that is formed within an aperture layer aperture 2036 of the EAL 2030. The lens structure 2010 can be shaped such that light from the backlight that passes through the lens structure 2010 is spread to regions where light that passes through an empty aperture layer aperture previously could not reach. This improves the viewing angle of the display. In some implementations, the lens structure 2010 can be made from a transparent material, such as SiO₂ or other transparent dielectric materials. The lens structure 2010 can be formed by depositing a layer of transparent material on exposed surfaces of the EAL and the mold with which the EAL 2030 is formed and selectively etching the material using graded tone etch masking.

In some implementations, apertures formed through the light blocking layer of the underlying substrate or shutter apertures formed through the shutters also can include light dispersion structures similar to the ones shown in FIGS. 13, 14A-14H or a lens structure 2010 similar to that shown in FIG. 15. In some other implementations, a color filter array can be coupled to or formed integrally with an EAL such that each EAL aperture is covered by a color filter. In such implementations, images can be formed by simultaneously displaying multiple color subfields (or subframes associated with multiple color subfields) using separate groups of shutter assemblies.

Certain shutter-based display apparatus utilize complex circuitry for driving the shutters of an array of pixels. In some implementations, the power consumed by the circuit to send a current through an electrical interconnect is proportional to the parasitic capacitance on the interconnect. As such, the power consumption of the display can be reduced by reducing the parasitic capacitance on the electrical interconnects. One way in which parasitic capacitance on an electrical interconnect can be reduced is by increasing the distance between the electrical interconnect and other conductive components.

However, as display manufacturers increase pixel density to improve display resolution, the size of each pixel is reduced. As such, the electrical components are laid out within a smaller space, decreasing the available space to separate adjacent electrical components. As a result, the power consumption due to parasitic capacitance is likely to increase. One way to reduce parasitic capacitance without compromising pixel size is by forming one or more electrical interconnects on top of an EAL of a display apparatus. By locating electrical interconnects on top of the EAL, one can introduce a large distance between the interconnects on top of the EAL from those below the EAL on the underlying substrate. This distance substantially reduces the parasitic capacitance between the electrical interconnects on top of the EAL and any conductive components formed on the underlying substrate. The decrease in capacitance yields a corresponding decrease in power consumption. It also increases the speed with which a signal propagates through the interconnects, increasing the speed with which the display can be addressed.

FIG. 16 shows a cross-sectional view of an example display apparatus 2100 having an EAL 2130. The display apparatus 2100 is substantially similar to the display apparatus 1000 shown in FIG. 5A except that the display apparatus 2100 includes an electrical interconnect 2110 formed on top of the EAL 2130.

In some implementations, the electrical interconnect 2110 can be formed on top of an anchor 2140 supporting the EAL 2130. In some implementations, the electrical interconnect 2110 can be electrically isolated from the EAL 2130 on which it is formed. In some such implementations, a layer of electrically insulating material is deposited on the EAL 2130 first and then the electrical interconnect 2110 can be formed on the electrically insulating material. In some implementations, the electrical interconnect 2110 may be a column interconnect, such as the data interconnect 808 shown in FIG. 3B. In some other implementations, the electrical interconnect 2110 can be a row interconnect, for example, the scan-line interconnect 806 shown in FIG. 3B. In some other implementations, the electrical interconnect 2110 can be a common interconnect, such as an actuation voltage interconnect 810 or a global update interconnect 812, also shown in FIG. 3B.

In some implementations, the electrical interconnect 2110 can be electrically coupled to a shutter 2120 of the display apparatus 2100. In some such implementations, the electrical interconnect 2110 is electrically directly coupled to the shutter 2120 via a conductive anchor 2140 that supports both the EAL 2130 and the underlying shutter assembly For example, in implementations in which the EAL 2130 includes a conductive material and an electrically insulating material is deposited over the EAL 2130, prior to depositing the material that will form the interconnect 2110, the insulating material can be patterned to expose a portion of the EAL 2130 that couples to and/or forms portions of the anchors 2140. Then, when the interconnect material is deposited, the interconnect material forms an electrical connection with the exposed portion of EAL, allowing current to flow from the electrical interconnect 2110, through the EAL 2130, down the anchor 2140, and onto the shutter 2120 supported by the anchor. In some implementations, the EAL 2130 is pixilated such that it includes a plurality of electrically isolated conductive regions. In some implementations, the electrical interconnect 2110 is configured to provide a voltage to electrical components of one or more of the electrically isolated conductive regions.

The display apparatus also includes several other electrical interconnects 2112 that are formed on top of an underlying transparent substrate 2102, similar to the transparent substrate 1002 shown in FIG. 5. In some implementations, the electrical interconnects 2112 can be one of column interconnects, row interconnects, or common interconnects. In some implementations, interconnects are selected for positioning on top of the EAL and under the EAL to increase the distance between switched interconnects, i.e., interconnects carrying voltages that are changed relatively frequently, such as the data interconnects. For example, in some implementations, row interconnects may be positioned on top of the EAL while data interconnects are positioned below the EAL on the substrate. Similarly, in some other implementations, row interconnects are placed below the EAL on the substrate, and the data interconnects are positioned on top of the EAL. Interconnects that are kept at a relatively constant voltage can be positioned relatively closer to one another as capacitance-related power consumption arises primarily as a result of switching events.

In some implementations, an EAL can support additional electrical components besides just electrical interconnects. For example, an EAL can support capacitors, transistors, or other forms of electrical components. An example of a display apparatus incorporating EAL-mounted electrical components is shown in FIG. 17.

FIG. 17 shows a perspective view of a portion of an example display apparatus 2200. The display apparatus includes a control matrix similar to the control matrix 860 of FIG. 3B. In the display apparatus 2200, the actuation voltage interconnect 810 and the charge transistor 845 are formed on top of an EAL 2230.

The EAL 2230 is supported by an anchor 2240 that also supports the underlying light obstructing component 807, in this case a shutter. More particularly, the load electrode 2210 of an actuator 2208 extends away from the anchor 2240 and connects to the light obstructing component 807. The load electrode 2210 provides both physical support for the light obstructing component 807, as well as an electrical connection to the actuation voltage interconnect 810, through the charge transistor 845, on top of the EAL 2230. The actuator also includes a drive electrode 2212, extending from a second anchor 2214, which couples to the underlying substrate, but not up to the EAL.

In operation, when a voltage is applied to the actuation voltage interconnect 810, the charge transistor 845 is switched ON, and current passes through the anchor 2240 and the load electrode 2210 to bring the voltage on the light obstructing component 807 up to the actuation voltage. At the same time, current flows through the anchor 2240 to an electrically isolated region 2250 on the underside of the EAL, such that the light obstructing component 807 and the electrically isolated region 2250 remain at the same potential.

To fabricate the EAL 2230, a conductive layer is deposited on top a mold, such as the mold 1599 shown in FIG. 10F. The conductive layer is then patterned to electrically isolate various regions of the conductive layer, such that each region corresponds to an underlying shutter assembly. An electric insulation layer is then deposited on top of the conductive layer. The insulation layer is patterned to expose portions of the conductive layer to allow interconnects or other electrical components formed on top of the EAL to make electrical connections with the EAL. The actuation voltage interconnects 810 and charge transistors 845 are then fabricated on top of the electric insulation layer using thin film lithographic processes, including the deposition and patterning of additional layers of dielectric, semi-conducting, and conductive materials. In some implementations, the actuation voltage interconnect 810, charge transistor 845, and any other electrical components formed on top of the EAL are formed using indium gallium zinc oxide (IGZO)-compatible manufacturing processes. For example, the charge transistor may include an IGZO channel. In some other implementations, some electrical components are formed using other conductive oxide materials or other group IV semiconductors. In some other implementations, electrical components formed using more traditional semiconductor materials, such as a-Si or low temperature polysilicon (LTPS).

While FIG. 17 only shows the fabrication of interconnects and transistors on top of the EAL, other electrical components can be formed directly on, or mounted to the EAL. For example, the EAL also can support one or more of the write-enabling transistor 830, the data storage capacitor 835, the update transistor 840, as well other switches, level shifters, repeaters, amplifiers, registers, and other integrated circuit components. For example, the EAL can support circuitry selected to support a touch-screen function.

In some other implementations in which the EAL supports one or more data interconnects (such as the data interconnects 808 shown in FIGS. 3A and 3B), the EAL also can support one more buffers along the interconnects to redrive signals passed down the interconnects to reduce loading on the interconnect. For example, each data interconnect may include between 1 and about 10 buffers along its length. The buffers, in some implementations, can be implemented using either one or two inverters. In some other implementations, more complex buffer circuits can be included. Typically, there would be insufficient room for such buffers on a display substrate. An EAL, however, in some implementations, can provide sufficient additional space for inclusion of such buffers to be feasible.

Certain display apparatus can be assembled by attaching a cover sheet that forms the front of the display to a rear transparent substrate. The cover sheet has a light blocking layer through which front apertures are formed. The transparent substrate includes a light blocking layer through which rear apertures are formed. The transparent substrate can support a plurality of display elements having light modulators, which correspond to the rear apertures formed through the light blocking layer. Misalignment of the front apertures relative to the corresponding underlying apertures when the cover sheet and transparent substrate are attached to one another can adversely affect display characteristics of the display apparatus. In particular, the misalignment can adversely affect one or more of the brightness, contrast ratio, and viewing angle of the display apparatus. Accordingly, when attaching the cover sheet to the transparent substrate, extra care is taken to make sure that the apertures are closely aligned with the respective display elements and rear apertures, resulting in increased costs and complexity of assembling such displays.

As an alternative, to overcome such misalignment issues, the front light blocking layer can be formed on or by the EAL instead of on the cover sheet. In some implementations to help reduce any light leakage from light passing through the EAL at a relatively low angle with respect to the EAL, the EAL is configured to adhere to the cover sheet, substantially sealing off any optical path for such angle to escape the display and negatively impact its contrast ratio. FIGS. 18A-18C show cross-sectional views of two display apparatus that incorporate such EALs.

FIG. 18A is a cross-sectional view of an example display apparatus 2300. The display apparatus 2300 is constructed in a MEMS-up configuration and includes an EAL 2330 adhered to rear surface of a coversheet 2308. The display apparatus 2300 includes shutter assemblies 2304 and an EAL 2330 fabricated on a MEMS substrate 2306. The EAL 2330 is constructed in a fashion similar to that described in relation to FIGS. 10A-10I. However, in constructing the EAL 2330, the aperture layer materials are deposited to be thinner, to increase their compliance. In contrast, the EAL 1541 was constructed to be substantially rigid.

The rear facing surface of the cover sheet 2308 is treated to promote stiction between the EAL 2330 and the cover sheet 2308. In some implementations, the surface treatment includes cleaning the rear surface using an oxygen or fluorine based plasma, as clean surfaces, particularly surfaces having a work of adhesion of greater than 20 mJ/m², tend to adhere together. In some other implementations, a hydrophilic coating is applied to the rear surface of the cover sheet 2308 and/or to the front surface of the EAL 2330. The EAL 2330 is then brought into contact with the rear surface of the cover sheet in a dry or humid environment. In a dry environment, hydroxide (OH) groups on the opposing surfaces attract one another. In the humid environment, moisture condenses on one or both surfaces resulting in the surfaces being attracted to and adhering to the opposing hydrophilic coating. In some other implementations, one or both surfaces may be coated with SiO₂ or SiNₓ with a low silicon concentration to promote adhesion. During the manufacturing process, after the cover sheet 2308 is brought into proximity to the MEMS substrate 2306, a charge is applied to the coversheet, attracting the EAL 2330 into contact with the rear surface of the cover sheet 2308. Upon contacting the rear surface of the cover sheet 2308, the EAL 2330 substantially permanently adheres to the surface. In some implementations, the adherence can be promoted by heating the surfaces.

FIGS. 18B and 18C show cross sectional views of additional example display apparatus 2350 and 2360. The display apparatus 2350 and 2360 are built in a MEMS-down configuration, in which an array of MEMS shutter assemblies and an EAL 2354 are fabricated on a front MEMS substrate 2356. The front MEMS substrate 2356 is attached to a rear aperture layer substrate 2358. The EAL 2354 is adhered to the rear aperture layer substrate 2358.

The display apparatus 2350 and 2360 differ from one another solely with respect to the location of a reflective layer 2362 incorporated into the display apparatus 2350 and 2360. The reflective layer 2362 provides for light recycling, by reflecting light that does not pass through apertures 2364 in the EALs 2354 back to respective backlights 2366 that are illuminating the display apparatus 2350 and 2360. In the display apparatus 2350, the reflective layer 2362 is deposited on top of the EAL 2354. Such implementations substantially increase alignment tolerances, as the apertures 2364 need not align with any particular feature on the rear aperture layer substrate 2358. However, in some circumstances, forming such a layer on the EAL 2354 may be costly or otherwise undesirable. In such situations, as shown in the display apparatus 2360 in FIG. 18B, the reflective layer 2362 can be deposited on the rear aperture layer substrate 2358 instead of on the EAL 2354.

In some implementations, the display apparatus can be designed such that the mold need not be fully removed to allow for proper display operation. For example, in some implementations, the display apparatus can be designed such that a portion of the mold remains under portions of the EAL, such as around the anchors supporting the EAL, after the release process is completed.

FIG. 19 shows a cross-sectional view of an example display apparatus 2400. The display apparatus 2400 is formed generally using the fabrication process to form the display apparatus 1500 described in relation to FIGS. 10A-10I. In contrast to this fabrication process, however, the fabrication process for the display apparatus does not fully remove the mold on which the display apparatus 2400 is constructed.

In particular, the display apparatus 2400 includes an anchor 2440 substantially similar to the anchor 1525 shown in FIG. 10I. The anchor 2440, however, is surrounded by mold material 2442, left after performing a release process. The release process entails partially releasing the display apparatus 2400 from the mold with which it is formed. In some implementations, the mold is partially removed by only exposing certain surfaces of the mold or limiting the exposure of the mold to a release agent. In some implementations, the portion of the mold that remains around the anchor 2440 can provide additional support to the anchor 2440.

In some implementations, the mold material can be selectively removed. For example, mold material that restricts the motion of a shutter 2420 or actuators 2422 coupled to the shutter 2420 should be removed. Further, mold material that obstructs the optical pathway between a rear aperture 2406 (formed through a light blocking layer 2404 deposited on a transparent substrate) and a corresponding EAL aperture 2436 (formed through an EAL 2430) is removed. That is, mold material that fills the area beneath the EAL aperture 2436 should be removed such that light from the backlight (not depicted) can pass through the EAL aperture 2436. However, mold material that does not restrict the motion of moving parts, such as the shutters 2420 and actuators 2422, and that does not interfere with the aforementioned transmission of light can be left in place. For example, sacrificial material 2442 beneath the other regions of the display apparatus, such as around the anchors 2440 or beneath light blocking portions of the EAL 2430 can remain. In this way, this sacrificial material 2442 can provide additional support to the anchors 2440 and the EAL 2430. Furthermore, since less of the sacrificial material is removed from the display apparatus 2400, the etching process can be completed quicker, thereby reducing manufacturing time.

FIGS. 20A and 20B are system block diagrams illustrating an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, electroluminescent (EL), organic light-emitting diode (OLED), super-twisted nematic liquid crystal display (STN LCD), or thin film transistor (TFT) LCD, or a non-flat-panel display, such as a cathode ray tube (CRT) or other tube device.

The components of the display device 40 are schematically illustrated in FIG. 20A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically shown in FIG. 20A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 801.11 standard, including IEEE 801.11 a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22, and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as the controller 134 described above with respect to FIG. 1B). Additionally, the array driver 22 can be a conventional driver or a bi-stable display driver. Moreover, the display array 30 can be a conventional display array or a bi-stable display array. In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, for example, a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are shown in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not shown can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus, comprising:
a transparent substrate;
a display element formed on the substrate;
a light blocking elevated aperture layer (EAL) supported over the substrate by an anchor formed on the substrate, the EAL having an aperture formed therethrough, the aperture corresponding to the display element; and
an electrical interconnect disposed on the EAL for carrying an electrical signal to the display element.

2. The apparatus of claim 1, further comprising at least one electrical component coupled to the electrical interconnect.

3. The apparatus of claim 2, wherein:
the electrical interconnect is coupled to a first electrical component of the at least one electrical component corresponding to the display element; and
the electrical interconnect is coupled to a second electrical component of the at least one electrical component corresponding to a second display element formed on the substrate.

4. The apparatus of claim 2, wherein the at least one electrical component includes at least one of a capacitor and transistor coupled to the electrical interconnect.

5. The apparatus of claim 4, wherein the transistor includes an indium gallium zinc oxide (IGZO) channel.

6. The apparatus of claim 1, wherein the electrical interconnect is electrically coupled to the anchor such that the anchor transmits the electrical signal to the display element.

7. The apparatus of claim 1, further comprising a second electrical interconnect disposed on the substrate electrically coupled to a plurality of display elements.

8. The apparatus of claim 1, wherein the electrical interconnect includes one of a data voltage interconnect, a scan-line interconnect or a global interconnect.

9. The apparatus of claim 1, further comprising a dielectric layer separating the electrical interconnect from the EAL.

10. The apparatus of claim 1, wherein the EAL includes an electrically isolated conductive region corresponding to the display element.

11. The apparatus of claim 10, wherein the electrically isolated conductive region is electrically coupled to a portion of the display element.

12. The apparatus of claim 11, wherein the electrically isolated conductive region is electrically coupled to the portion of the display element via a second anchor that supports the display element over the substrate.

13. The apparatus of claim 11, wherein the anchor supporting the EAL over the substrate also supports a portion of the display element over the substrate, and wherein the electrically isolated conductive region is electrically coupled to the suspended portion of the display element via the anchor.

14. The apparatus of claim 1, wherein the display element includes a microelectromechanical systems (MEMS) shutter-based display element.

15. The apparatus of claim 1, further comprising:
a display;
a processor that is configured to communicate with the display, the processor being configured to process image data; and
a memory device that is configured to communicate with the processor.

16. The apparatus of claim 15, further comprising:
a driver circuit configured to send at least one signal to the display; and wherein
the processor is further configured to send at least a portion of the image data to the driver circuit.

17. The apparatus of claim 15, further comprising:
an image source module configured to send the image data to the processor, wherein the image source module includes at least one of a receiver, transceiver, and transmitter.

18. The apparatus of claim 15, further comprising:
an input device configured to receive input data and to communicate the input data to the processor.

19. A method of manufacturing a display apparatus, comprising:
providing a transparent substrate;
forming a display element on the substrate;
forming a light blocking layer over the substrate supported by an anchor formed on the substrate;
forming an aperture through the light blocking layer to form an elevated aperture layer (EAL), the aperture corresponding to the display element; and
forming an electrical interconnect on top of the EAL for carrying an electrical signal to the display element.

20. The method of claim 19, further comprising, depositing a layer of electrically insulating material over the EAL prior to forming the electrical interconnect.

21. The method of claim 20, wherein:
the EAL includes a conductive material and the method further includes patterning the layer of electrically insulating material to expose portions of the EAL prior to forming the electrical interconnect, and
forming the electrical interconnect includes depositing a layer of conductive material over the layer of electrically insulating material and patterning the layer of electrically conductive material to form the electrical interconnect such that a portion of the electrical interconnect contacts the exposed portion of the EAL.

22. The method of claim 21, further comprising depositing a layer of semiconducting material over the formed electrical interconnect and patterning the layer of semiconductor channel to form a portion of a transistor.

23. The method of claim 22, wherein the layer of semi-conducting material includes a metal oxide.

24. The method of claim 19, further comprising forming an electrical interconnect on the substrate prior to forming the display element.
